(19) United States
(12) Patent Application Publication
(10) Pub. No.: US 2026/0148771 A1
(43) Pub. Date: May 28, 2026

(54) MEMORY DEVICE AND MEMORY SYSTEM

(71) Applicant: MACRONIX INTERNATIONAL CO., LTD., HSINCHU (TW)

(72) Inventors: Po-Hao TSENG, Taichung City (TW); Tian-Cih BO, Zhubei City (TW)

(21) Appl. No.: 19/089,087

(22) Filed: Mar. 25, 2025

Related U.S. Application Data
(60) Provisional application No. 63/725,526, filed on Nov. 26, 2024.

(51) Int. Cl. G11C 16/26; G11C 16/04

(52) U.S. Cl. CPC G11C 16/26; G11C 16/0483

(57) ABSTRACT

A memory device includes a first memory block pair. The first memory block pair stores a first stored data bit, and compares the first stored data bit and a first input bit, to generate a first current signal. The first memory block pair includes a first memory block and a second memory block. The first memory block generates first string current signals according to a first string select line signal The second memory block generates second string current signals according to a second string select line signal. The first and second string select line signals are configured to carry the first input bit, and the first memory block pair sums the first string current signals and the second string current signals to generate the first current signal.

### CROSS-REFERENCE TO RELATED APPLICATION

This application claims priority to U.S. Provisional Application No. 63/725,526, filed Nov. 26, 2024, which is herein incorporated by reference in its entirety.

### BACKGROUND

### Technical Field

The present disclosure relates to a memory technique. More particularly, the present disclosure relates to a memory device and a memory system.

### Description of Related Art

The Euclidean distance is the shortest distance between two points in the Euclidean space, and can be used as a common metric to measure the similarity between two data points. The Euclidean distance is also used in various fields such as geometry, data mining, deep learning and others. However, a memory device configured for computing the Euclidean distance may have poor reliability and complicate operations. Thus, techniques associated with the designing memory device with good reliability and simple operations for calculating the Euclidean distance are important issues in the field.

### SUMMARY

The present disclosure provides a memory device. The memory device includes a first memory block pair. The first memory block pair is configured to store a first stored data bit, and configured to compare the first stored data bit and a first input bit, to generate a first current signal. The first memory block pair includes a first memory block and a second memory block. The first memory block is configured to generate a plurality of first string current signals according to a first string select line signal The second memory block is configured to generate a plurality of second string current signals according to a second string select line signal, wherein the first string select line signal and the second string select line signal are configured to carry the first input bit, and the first memory block pair is further configured to sum the plurality of first string current signals and the plurality of second string current signals to generate the first current signal.

In some embodiments, the first memory block is further configured to sum the plurality of first string current signals to generate a second current signal, the second memory block is further configured to sum the plurality of second string current signals to generate a third current signal, when the first stored data bit has a first logic value and the first input bit has the first logic value or a second logic value, each of the second current signal and the third current signal has a first current level.

In some embodiments, when the first stored data bit has the second logic value and the first input bit has the first logic value or the second logic value, the second current signal and the third current signal have a second current level and the first current level, respectively, and the second current level is larger than the first current level.

In some embodiments, when the first stored data bit has a third logic value and the first input bit has the first logic value or the second logic value, the second current signal and the third current signal have a third current level and the first current level, respectively, and the third current level is larger than the second current level.

In some embodiments, when the first stored data bit has a fourth logic value and the first input bit has the first logic value or the second logic value, the second current signal and the third current signal have a fourth current level and the first current level, respectively, and the fourth current level is larger than the third current level.

In some embodiments, when the first stored data bit has the second logic value and the first input bit has the third logic value or a fourth logic value, the second current signal and the third current signal have the first current level and the third current level, respectively.

In some embodiments, when the first input bit has a first logic value or a second logic value, the first string select line signal and the second string select line signal have a first voltage level and a second voltage level, respectively, and when the first input bit has a third logic value or a fourth logic value, the first string select line signal and the second string select line signal have the second voltage level and the first voltage level, respectively.

In some embodiments, the first memory block comprising a first memory string and a second memory string, when the first stored data bit has the first logic value, each of the first memory string and the second memory string has a first resistance, and when the first stored data bit has the second logic value, the first memory string and the second memory string have a second resistance and the first resistance, respectively.

In some embodiments, when the first stored data bit has the third logic value, each of the first memory string and the second memory string has the second resistance.

In some embodiments, the first memory block further comprising a third memory string, when the first stored data bit has the third logic value, the third memory string has the first resistance, and when the first stored data bit has the fourth logic value, each of the first memory string, the second memory string and the third memory string has the second resistance.

The present disclosure provides a memory device. The memory device includes a first memory block and a second memory block. The first memory block is configured to generate a plurality of first string current signals according to a first string select line signal, and sum the plurality of first string current signals to generate a first current signal The second memory block is configured to generate a plurality of second string current signals according to a second string select line signal, and sum the plurality of second string current signals to generate a second current signal, wherein the first string select line signal and the second string select line signal are configured to carry a first input bit, the first memory block and the second memory block are further configured to store a first stored data bit, and when a logic value of the first input bit is equal to a logic value of the first stored data bit, a current level of the first current signal is equal to a current level of the second current signal.

In some embodiments, when the logic value of the first input bit is different from the logic value of the first stored data bit, the current level of the first current signal is different from the current level of the second current signal.

In some embodiments, the first memory block and the second memory block include a first switch element and a second switch element, respectively, when the first stored data bit has a first logic value, the first switch element and the second switch element have a first threshold voltage level and a second threshold voltage level, respectively, and when the first stored data bit has a second logic value, each of the first switch element and the second switch element has the second threshold voltage level.

In some embodiments, when the first stored data bit has a third logic value, the first switch element and the second switch element have the second threshold voltage level and the first threshold voltage level, respectively.

In some embodiments, the first memory block and the second memory block include a first switch element and a second switch element, respectively, when the first stored data bit has a first logic value, the first switch element and the second switch element have a first threshold voltage level and a second threshold voltage level, respectively, and when the first stored data bit has a second logic value, each of the first switch element and the second switch element has the second threshold voltage level.

In some embodiments, when the first stored data bit has a third logic value, each of the first switch element and the third switch element has the second threshold voltage level, and each of the second switch element and the fourth switch element has the first threshold voltage level.

In some embodiments, the first memory block and the second memory block comprise a third switch element and a fourth switch element, respectively, the third switch element and a fourth switch element are configured to receive the first string select line signal and the second string select line signal, respectively, when the first input bit has the first logic value or the second logic value, the first string select line signal and the second string select line signal has a first voltage level and a second voltage level, respectively, when the first input bit has a third logic value or a fourth logic value, the first string select line signal and the second string select line signal has the second voltage level and the first voltage level, respectively, the first logic value, the second logic value, the third logic value and the fourth logic value are different from each other.

The present disclosure provides a memory system. The memory system includes a plurality of first memory blocks and a plurality of second memory blocks. The plurality of first memory blocks are configured to store a plurality of first stored data bits, and configured to compare the plurality of first stored data bits with a plurality of input bits to generate a first bit line signal. The plurality of second memory blocks are configured to store a plurality of second stored data bits, and configured to compare the plurality of second stored data bits with the plurality of input bits to generate a second bit line signal. The plurality of first memory blocks and the plurality of second memory blocks are further configured to receive a plurality of string select line signals, and the plurality of string select line signals are configured to carry the plurality of input bits.

In some embodiments, the plurality of first memory blocks comprise a third memory block and a fourth memory block respectively configured to receive a first string select line signal and a second string select line signal, the third memory block and the fourth memory block are configured to store a third stored data bit in the plurality of first stored data bits, in response to a first input bit in the plurality of input bits having a first logic value or a second logic value, the first string select line signal and the second string select line signal have a first voltage level and a second voltage level, respectively, and the first voltage level is larger than the second voltage level.

In some embodiments, the plurality of second memory blocks comprise a fifth memory block and a sixth memory block respectively configured to receive the first string select line signal and the second string select line signal, the fifth memory block and the sixth memory block configured to store a fourth stored data bit in the plurality of second stored data bits, in response to the third stored data bit having a third logic value, the third memory block and the fourth memory block are configured to generate a first current signal having a first current level, in response to the fourth stored data bit having the first logic value, the third memory block and the fourth memory block are configured to generate a second current signal having a second current level, and the first current level is larger than the second current level.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a part of a memory device illustrated according to some embodiments of present disclosure.

FIG. 1B to FIG. 1H are schematic diagrams of other conditions of the memory device, illustrated according to some embodiments of present disclosure.

FIG. 2A is schematic diagram of a memory device, illustrated according to some embodiments of present disclosure.

FIG. 2B to FIG. 2C are schematic diagrams of the memory blocks shown in FIG. 1A, illustrated according to some embodiments of present disclosure.

FIG. 2D to FIG. 2F are schematic diagrams of other conditions of the memory device shown in FIG. 2A, illustrated according to some embodiments of present disclosure.

FIG. 3 is a schematic diagram of the memory device shown in FIG. 2A performing pseudo-Euclidean computing of 4-levels to the input bit, illustrated according to some embodiments of present disclosure.

FIG. 4A is a schematic diagram of the memory device performing the search operation, illustrated according to some embodiments of present disclosure.

FIG. 4B to FIG. 4H are schematic diagrams of other conditions of the memory device performing the search operation, illustrated according to some embodiments of present disclosure.

FIG. 5A to FIG. 5C are tables of the memory device performing the search operation, illustrated according to some embodiments of present disclosure.

FIG. 6A is a schematic diagram of a memory system, illustrated according to some embodiments of present disclosure.

FIG. 6B is a schematic diagram of further details of the memory device, illustrated according to some embodiments of present disclosure.

FIG. 6C to FIG. 6F are schematic diagrams of further details of the memory blocks, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

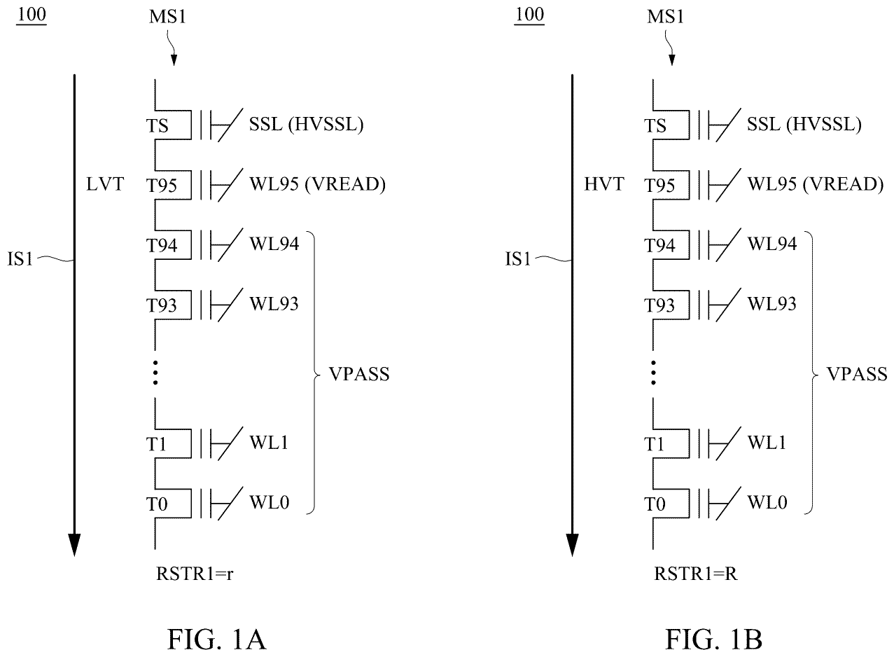

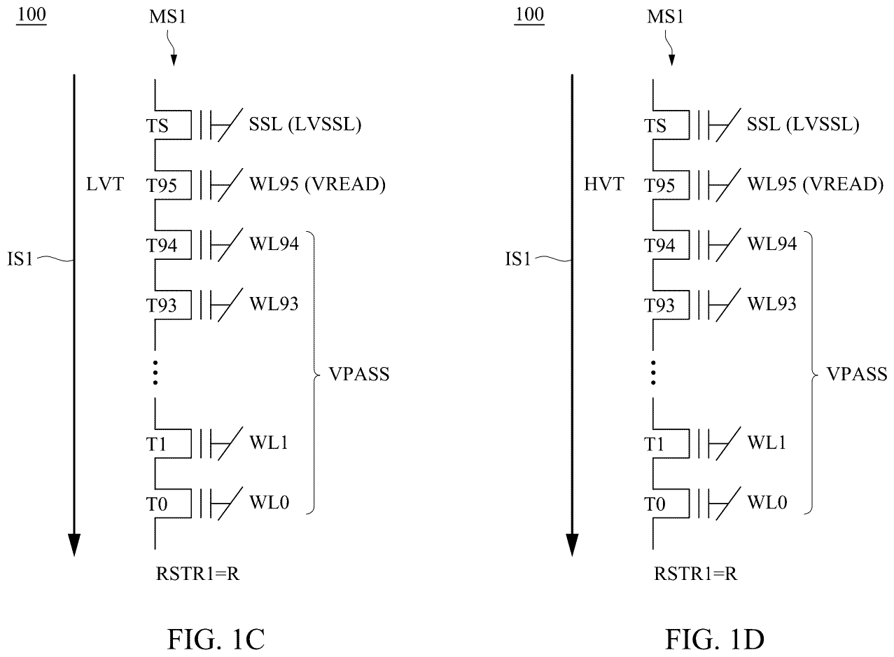

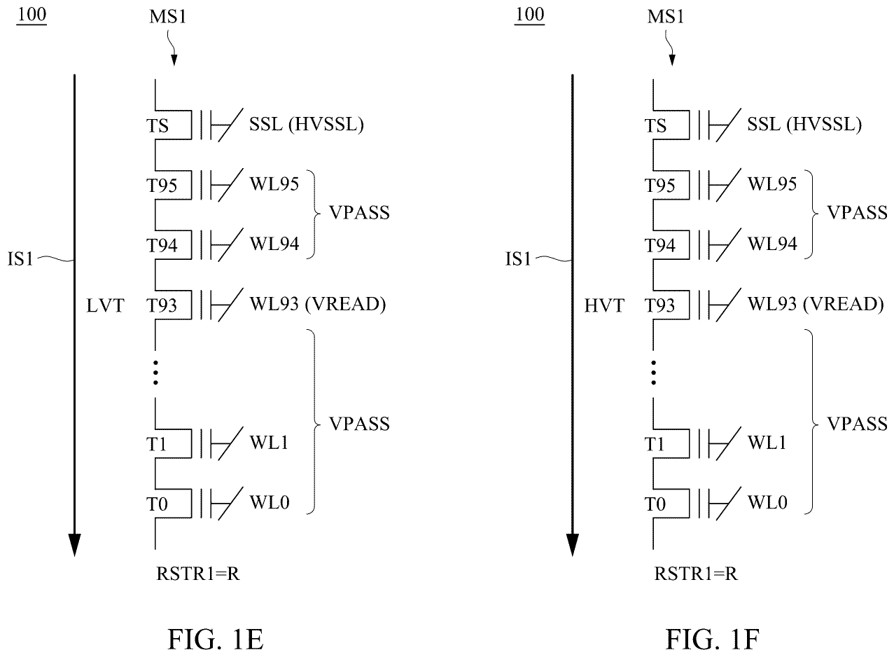

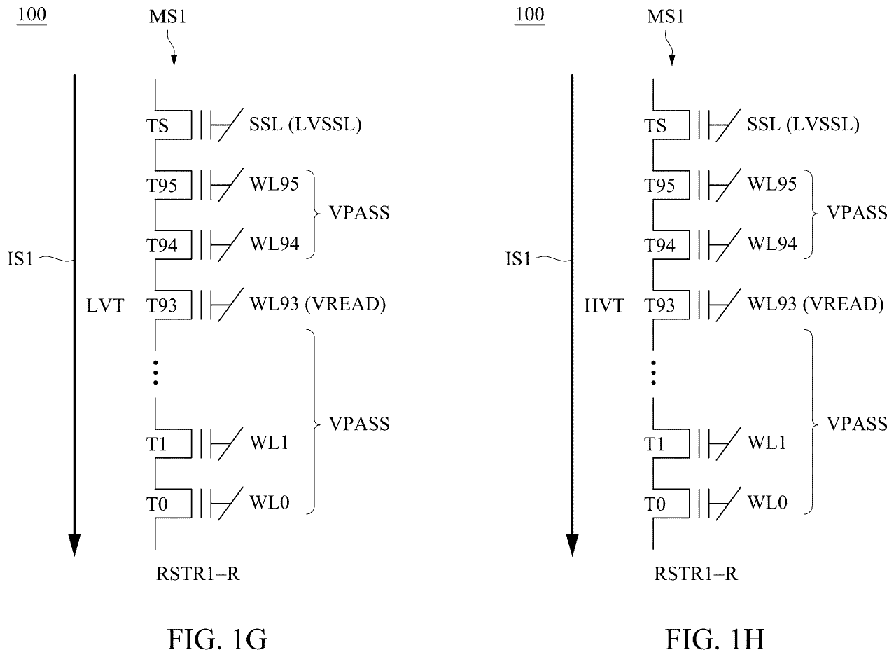

FIG. 1A is a schematic diagram of a part of a memory device 100, illustrated according to some embodiments of present disclosure. In some embodiments, the memory device 100 includes multiple memory strings, such as the memory string MS1. The memory string MS1 is configured to generate a string current signal IS1.

As shown in FIG. 1A, the memory string MS1 can includes multiple switch elements, such as switch elements TS and T0-T95. However, the embodiments of present disclosure are not limited to this. In various embodiments, the memory string MS1 can include various quantities of switch elements, that is, 95 can be substituted with other positive integers.

In some embodiments, the switch elements T0-T95 and TS are coupled in series with each other and are arranged in order. Control terminals of the switch elements T0-T95 and TS are configured to receive the word line signals WL0-WL95 and a string select line signal SSL, respectively.

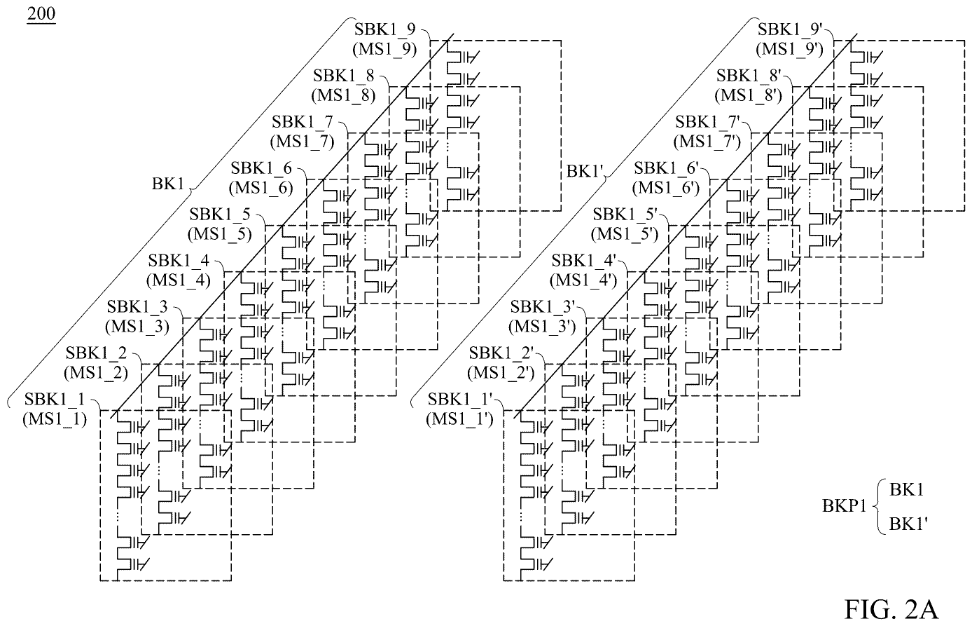

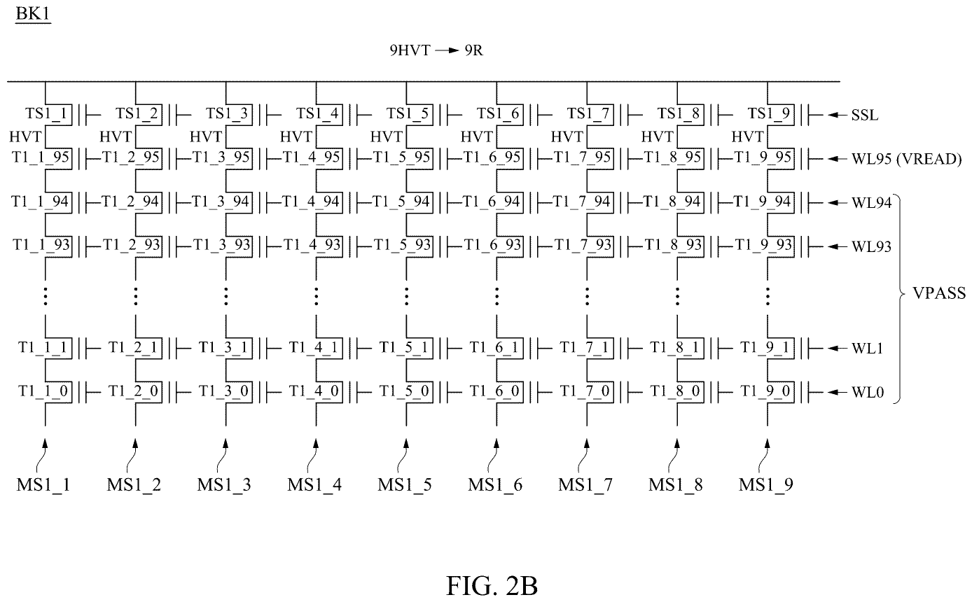

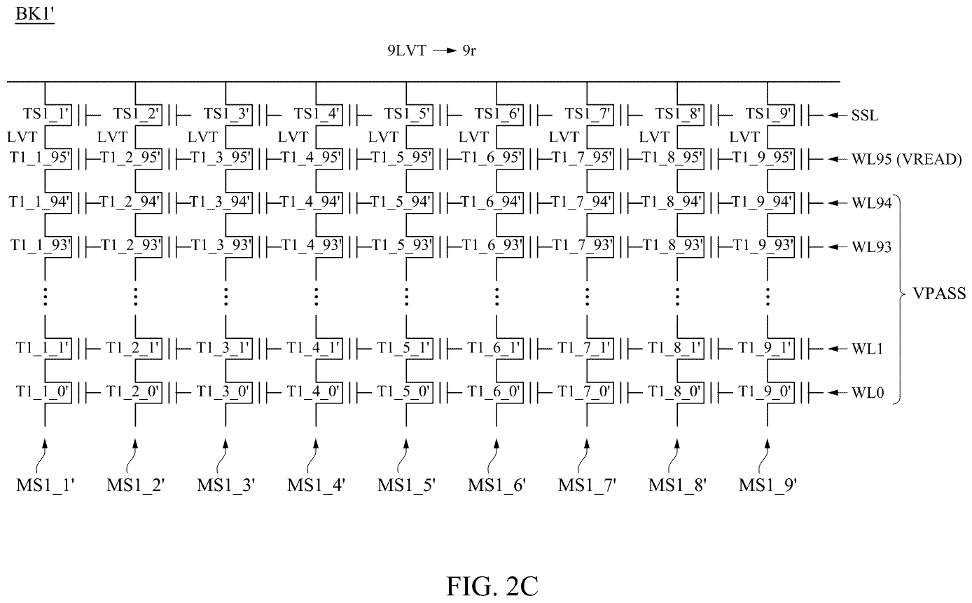

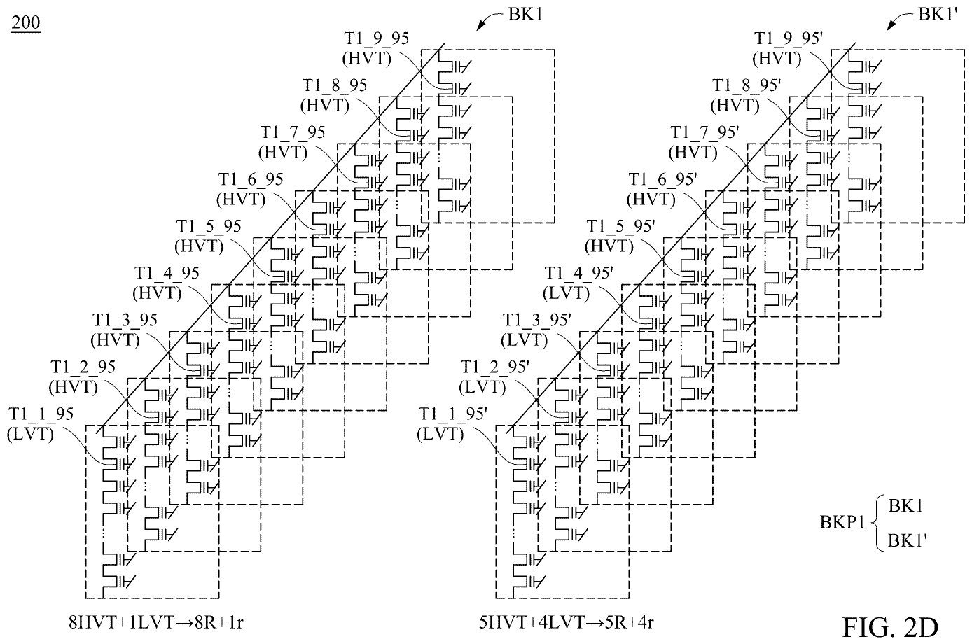

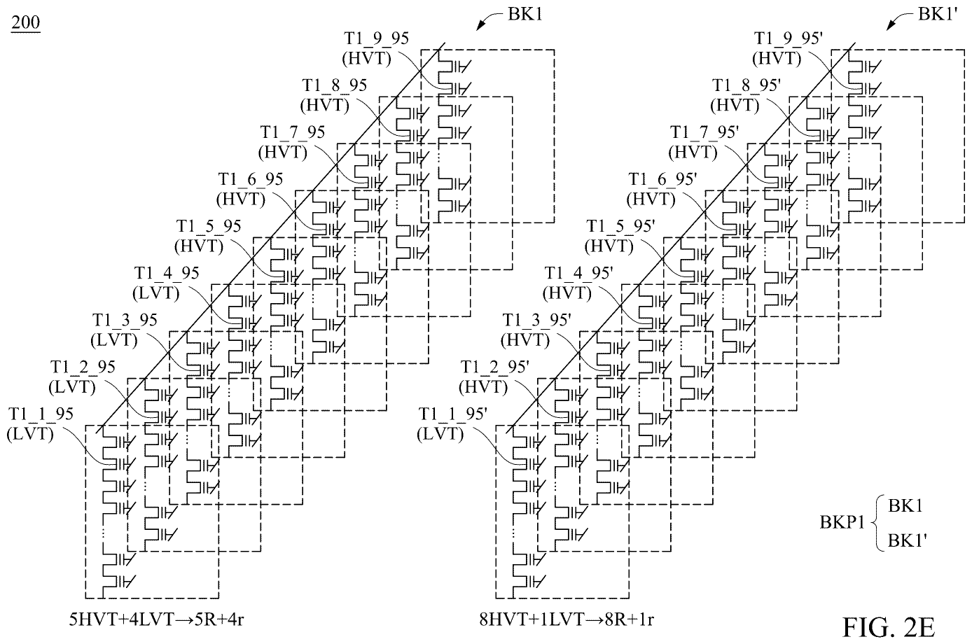

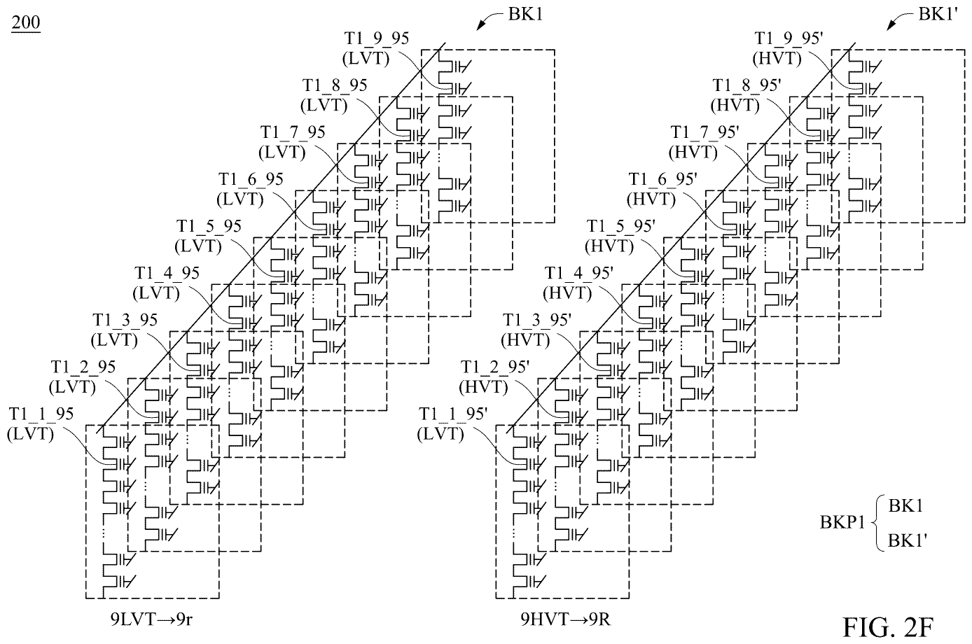

In some embodiments, the switch elements T0-T95 can configured to store corresponding stored data bits, and have corresponding threshold voltage levels HVT or LVT. The threshold voltage level HVT is larger than the threshold voltage level LVT. For example, the threshold voltage level HVT is between 3 volt and 4 volt, and the threshold voltage level LVT is between 0 volt and 1 volt. Details of the switch elements and the stored data bits are further described below with the embodiments associated with FIG. 2A to FIG. 2D.

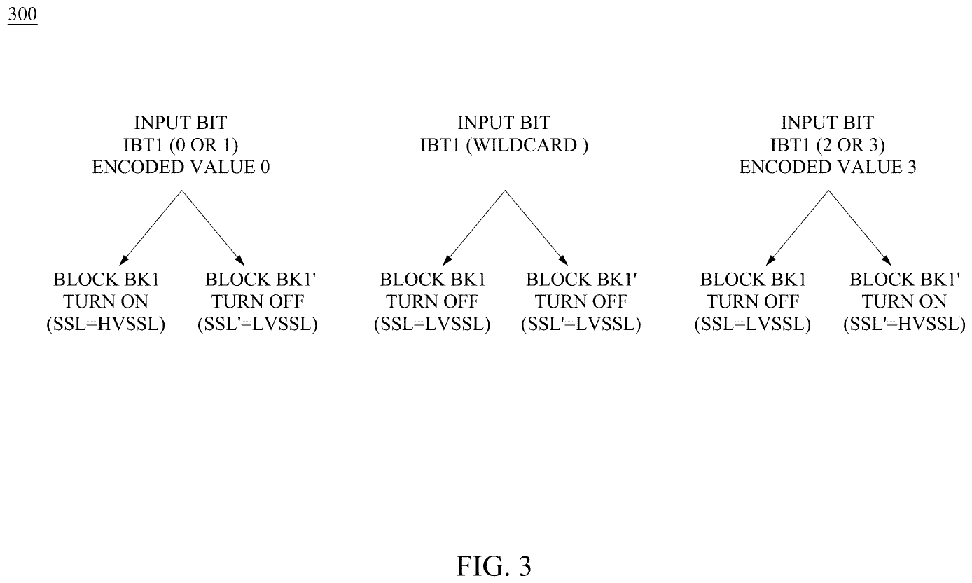

In some embodiments, the string select line signal SSL can carry a corresponding input bit, and have a corresponding voltage level HVSSL or LVSSL. When the string select line signal SSL has the voltage level HVSSL, the switch element TS is turned on. When the string select line signal SSL has the voltage level LVSSL, the switch element TS is turned off. In some embodiments, the voltage level HVSSL is larger than the voltage level LVSSL. For example, the voltage level HVSSL is approximately equal to 3 volt, and the voltage level LVSSL is approximately equal to 0 volt. Details of the string select line signal SSL and the input bit are further described below with the embodiments associated with FIG. 3.

In various embodiments, one of the word line signals WL0-WL95 has a read voltage level VREAD, to read a corresponding stored data bit. For example, in the embodiment shown in FIG. 1A, the word line signal WL95 has the read voltage level VREAD, to read a read voltage level VREAD, to read corresponding to the switch element T95. In some embodiments, the read voltage level VREAD is larger than the threshold voltage level LVT and is smaller than the threshold voltage level HVT. For example, the read voltage level VREAD can be 2 volt.

Correspondingly, when a switch element has the threshold voltage level LVT and a control terminal of the switch element has the read voltage level VREAD, the switch element is turned on. When a switch element has the threshold voltage level HVT and a control terminal of the switch element has the read voltage level VREAD, the switch element is turned off.

On the other hand, in the embodiment shown in FIG. 1A, each of the word line signals WL0-WL94 has a pass voltage level VPASS, such that each of the switch elements T0-T94 is turned on. The string select line signal SSL has the voltage level HVSSL, such that the switch element TS is turned on. At this moment, a string resistor RSTR1 of the memory string MS1 is determined by the threshold voltage level of the switch element T95. In some embodiments, the pass voltage level VPASS is larger than the threshold voltage level HVT. For example, the pass voltage level VPASS can be between 6 volt and 7 volt.

In the embodiment shown in FIG. 1A, the switch element T95 has the threshold voltage level LVT, such that the string resistor RSTR1 has a resistance r. Correspondingly, the string current signal IS1 has a current level ISL1.

FIG. 1B is a schematic diagram of another condition of the memory device 100, illustrated according to some embodiments of present disclosure. In the embodiment shown in FIG. 1B, each of the word line signals WL0-WL94 has the pass voltage level VPASS, such that each of the switch elements T0-T94 is turned on. The string select line signal SSL has the voltage level HVSSL, such that the switch element TS is turned on.

At this moment, in response to the switch element T95 has the threshold voltage level HVT and the word line signal WL95 has the read voltage level VREAD, the switch element T95 is turned off, such that the string resistor RSTR1 has a resistance R. In which the resistance R corresponds to a memory string with a switch element being turned off. Correspondingly, the string current signal IS1 has a current level ISL2. Referring to FIG. 1A and FIG. 1B, the resistance R is larger than the resistance r. Correspondingly, the current level ISL2 is smaller than the current level ISL1, and can be referred to as the zero current level.

FIG. 1C is a schematic diagram of another condition of the memory device 100, illustrated according to some embodiments of present disclosure. In the embodiment shown in FIG. 1C, each of the word line signals WL0-WL94 has the pass voltage level VPASS, such that each of the switch elements T0-T94 is turned on. In response to the switch element T95 has the threshold voltage level HVT and the word line signal WL95 has the read voltage level VREAD, the switch element T95 is turned off. At this moment, the string select line signal SSL has the voltage level LVSSL, such that the switch element TS is turned off. Correspondingly, the string resistor RSTR1 has the resistance R. Correspondingly, the string current signal IS1 has the current level ISL2.

FIG. 1D is a schematic diagram of another condition of the memory device 100, illustrated according to some embodiments of present disclosure. In the embodiment shown in FIG. 1D, each of the word line signals WL0-WL94 has the pass voltage level VPASS, such that each of the switch elements T0-T94 is turned on. In response to the switch element T95 has the threshold voltage level HVT and the word line signal WL95 has the read voltage level VREAD, the switch element T95 is turned off. At this moment, the string select line signal SSL has the voltage level LVSSL, such that the switch element TS is turned on. Correspondingly, the string resistor RSTR1 has the resistance R. The string current signal IS1 has the current level ISL2.

FIG. 1E is a schematic diagram of another condition of the memory device 100, illustrated according to some embodiments of present disclosure. In the embodiment shown in FIG. 1E, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level LVT and the word line signal WL93 has the read voltage level VREAD, the switch element T93 is turned on. At this moment, the string select line signal SSL has the voltage level HVSSL, such that the switch element TS is turned on. Correspondingly, the string resistor RSTR1 has the resistance r. The string current signal IS1 has the current level ISL1.

FIG. 1F is a schematic diagram of another condition of the memory device 100, illustrated according to some embodiments of present disclosure. In the embodiment shown in FIG. 1F, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level HVT and the word line signal WL93 has the read voltage level VREAD, the switch element T93 is turned off. At this moment, the string select line signal SSL has the voltage level HVSSL, such that the switch element TS is turned on. Correspondingly, the string resistor RSTR1 has the resistance R. The string current signal IS1 has the current level ISL2.

FIG. 1G is a schematic diagram of another condition of the memory device 100, illustrated according to some embodiments of present disclosure. In the embodiment shown in FIG. 1G, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level LVT and the word line signal WL93 has the read voltage level VREAD, the switch element T93 is turned on. At this moment, the string select line signal SSL has the voltage level LVSSL, such that the switch element TS is turned off. Correspondingly, the string resistor RSTR1 has the resistance R. The string current signal IS1 has the current level ISL2.

FIG. 1H is a schematic diagram of another condition of the memory device 100, illustrated according to some embodiments of present disclosure. In the embodiment shown in FIG. 1H, the memory device 100 is configured to read a stored data bit corresponding to the switch element. Correspondingly, the word line signal WL93 has the read voltage level VREAD. Each of the word line signals WL0-WL92 and WL94-WL95 has the pass voltage level VPASS, such that each of the switch elements T0-T92 and T94-T95 is turned on. In response to the switch element T93 has the threshold voltage level HVT and the word line signal WL93 has the read voltage level VREAD, the switch element T93 is turned off. At this moment, the string select line signal SSL has the voltage level HVSSL, such that the switch element TS is turned on. Correspondingly, the string resistor RSTR1 has the resistance R. The string current signal IS1 has the current level ISL2.

FIG. 2A is schematic diagram of a memory device 200, illustrated according to some embodiments of present disclosure. As shown in FIG. 2A, the memory device 200 includes a memory block pair BKP1. In some embodiments, the memory block pair BKP1 is configured to store a stored data bit SDT1.

The memory block pair BKP1 includes a memory blocks BK1 and BK1′. The memory block BK1 includes sub-blocks SBK1_1-SBK1_9, and the memory block BK1′ includes sub-blocks SBK1_1′-SBK1_9′. The sub-blocks SBK1_1-SBK1_9 and SBK1_1′-SBK1_9′ include memory strings MS1_1-MS1_9 and MS1_1′-MS1_9′, respectively. However, the embodiments of present disclosure are not limited to this. In various embodiments, one sub-block can includes various quantities of memory strings.

Referring to FIG. 1A to FIG. 2A, configurations of each of the memory strings MS1_1-MS1_9 and MS1_1′-MS1_9′ are similar with the configuration of the memory string MS1. Therefore, for brevity, some descriptions are not repeated. Details of the memory strings MS1_1-MS1_9 and MS1_1′-MS1_9′ are further described below with the embodiments associated with FIG. 2B and FIG. 2C.

FIG. 2B is a schematic diagram of the memory block BK1 shown in FIG. 2A, illustrated according to some embodiments of present disclosure. As shown in FIG. 2B, the memory string MS1_1 includes switch elements T1_1_0-T1_1_95 and TS1_1 coupled in series and arranged in order. The memory string MS1_2 includes switch elements T1_2_0-T1_2_95 and TS1_2 coupled in series and arranged in order, and so on. The memory string MS1_8 includes switch elements T1_8_0-T1_8_95 and TS1_8 coupled in series and arranged in order. The memory string MS1_9 includes switch elements T1_9_0-T1_9_95 and TS1_9 coupled in series and arranged in order.

In some embodiments, each of control terminals of the switch elements TS1_1-TS1_9 is configured to receive the string select line signal SSL. Each of the control terminals of the switch elements T1_1_0-T1_9_0 is configured to receive the word line signal WL0. Each of the control terminals of the switch elements T1_1_1-T1_9_1 is configured to receive the word line signal WL1, and so on. Each of the control terminals of the switch elements T1_1_93-T1_9_93 is configured to receive the word line signal WL93. Each of the control terminals of the switch elements T1_1_94-T1_9_94 is configured to receive the word line signal WL94. Each of the control terminals of the switch elements T1_1_95-T1_9_95 is configured to receive the word line signal WL95.

FIG. 2C is a schematic diagram of the memory block BK1′ shown in FIG. 2A, illustrated according to some embodiments of present disclosure. As shown in FIG. 2C, the memory string MS1_1′ includes switch elements T1_1_0′-T1_1_95′ and TS1_1′ coupled in series and arranged in order. The memory string MS1_2′ includes switch elements T1_2_0′-T1_2_95′ and TS1_2′ coupled in series and arranged in order, and so on. The memory string MS1_8′ includes switch elements T1_8_0′-T1_8_95′ and TS1_8′ coupled in series and arranged in order. The memory string MS1_9′ includes switch elements T1_9_0′-T1_9_95′ and TS1_9′ coupled in series and arranged in order.

In some embodiments, each of control terminals of the switch elements TS1_1′-TS1_9′ is configured to receive the string select line signal SSL′. Each of the control terminals of the switch elements T1_1_0′-T1_9_0′ is configured to receive the word line signal WL0. Each of the control terminals of the switch elements T1_1_1′-T1_9_1′ is configured to receive the word line signal WL1, and so on. Each of the control terminals of the switch elements T1_1_93′-T1_9_93′ is configured to receive the word line signal WL93. Each of the control terminals of the switch elements T1_1_94′-T1_9_94′ is configured to receive the word line signal WL94. Each of the control terminals of the switch elements T1_1_95′-T1_9_95′ is configured to receive the word line signal WL95.

In the embodiment shown in FIG. 2C and FIG. 2B, the memory device 200 performs the search operation to a memory cell of the 95th level. Alternatively stated, the memory device 200 performs the search operation to the stored data bit SDT1 stored by the switch elements T1_1_95-T1_9_95 and T1_1_95′-T1_9_95′. Correspondingly, the word line signal WL95 has the read voltage level VREAD, and each of the word line signals WL0-WL94 has the pass voltage level VPASS.

In other embodiments, the memory device 200 can also performs the search operation to memory cells of other levels, to read stored data bits stored by the other levels. For example, referring to FIG. 1E to FIG. 1H and FIG. 2B to FIG. 2C, the memory device 200 can also performs the search operation to a memory cell of the 93th level. At this moment, the word line signal WL93 has the read voltage level VREAD, and each of the word line signals WL0-WL92 and WL94-WL95 has the pass voltage level VPASS.

In the embodiment shown in FIG. 2C and FIG. 2B, the stored data bit SDT1 has a logic value 0. Correspondingly, each of the switch elements T1_1_95-T1_9_95 has the threshold voltage level HVT, and each of the switch elements T1_1_95′-T1_9_95′ has the threshold voltage level LVT.

In response to the word line signal WL93 having the read voltage level VREAD, each of the switch elements T1_1_95-T1_9_95 is turned off, and each of the switch elements T1_1_95-T1_9_95 is turned on. Correspondingly, each of the memory strings MS1_1-MS1_9 has the resistance R, and each of the memory strings MS1_1′-MS1_9′ has the resistance r. Alternatively stated, the memory block BK1 has 9 memory strings MS1_1-MS1_9 with the resistance R, and memory block BK1′ has 9 memory strings MS1_1′-MS1_9′ with the resistance r.

FIG. 2D is a schematic diagram of another condition of the memory device 200 shown in FIG. 2A, illustrated according to some embodiments of present disclosure. Referring to FIG. 2B to FIG. 2D, the embodiment shown in FIG. 2D is an alternative embodiment of the embodiment shown in FIGS. 2B and 2C. Therefore, for brevity, some descriptions are not repeated, and some labels are not shown in FIG. 2D. For example, the labels of the memory strings MS1_1-MS1_9 and MS1_1′-MS1_9′ are not shown in FIG. 2D.

In the embodiment shown in FIG. 2D, the stored data bit SDT1 has a logic value 1. Correspondingly, each of the switch elements T1_2_95-T1_9_95 and T1_5_95′-T1_9_95′ has the threshold voltage level HVT and is turned off, and each of the switch elements T1_1_95 and T1_1_95′-T1_9_95′ has the threshold voltage level LVT and is turned on.

At this moment, each of the memory strings MS1_2-MS1_9 and MS1_5′-MS1_9′ has the resistance R, and each of the memory strings MS1_1 and MS1_1′-MS1_4′ has the resistance r. Alternatively stated, the memory block BK1 has 8 memory strings MS1_2-MS1_9 with the resistance R and 1 memory string MS1_1 with the resistance r, and the memory block BK1′ has 5 memory strings MS1_5′-MS1_9'with the resistance R and 4 memory strings MS1_1′-MS1_4'with the resistance r.

FIG. 2E is a schematic diagram of another condition of the memory device 200 shown in FIG. 2A, illustrated according to some embodiments of present disclosure. Referring to FIG. 2B to FIG. 2E, the embodiment shown in FIG. 2E is an alternative embodiment of the embodiment shown in FIGS. 2B and 2C. Therefore, for brevity, some descriptions are not repeated, and some labels are not shown in FIG. 2E. For example, the labels of the memory strings MS1_1-MS1_9 and MS1_1′-MS1_9′ are not shown in FIG. 2E.

In the embodiment shown in FIG. 2E, the stored data bit SDT1 has a logic value 2. Correspondingly, each of the switch elements T1_5_95-T1_9_95 and T1_2_95′-T1_9_95′ has the threshold voltage level HVT and is turned off, and each of the switch elements T1_1_95-T1_4_95 and T1_1_95′ has the threshold voltage level LVT and is turned on.

At this moment, each of the memory strings MS1_5-MS1_9 and MS1_2′-MS1_9′ has the resistance R, and each of the memory strings MS1_1′ and MS1_1-MS1_4 has the resistance r. Alternatively stated, the memory block BK1 has 5 memory strings MS1_5-MS1_9 with the resistance R and 4 memory strings MS1_1-MS1_4 with the resistance r, and the memory block BK1′ has 8 memory strings MS1_2′-MS1_9′ with the resistance R and 1 memory string MS1_1′ with the resistance r.

FIG. 2F is a schematic diagram of another condition of the memory device 200 shown in FIG. 2A, illustrated according to some embodiments of present disclosure. Referring to FIG. 2B to FIG. 2F, the embodiment shown in FIG. 2F is an alternative embodiment of the embodiment shown in FIGS. 2B and 2C. Therefore, for brevity, some descriptions are not repeated, and some labels are not shown in FIG. 2F. For example, the labels of the memory strings MS1_1-MS1_9 and MS1_1′-MS1_9′ are not shown in FIG. 2F.

In the embodiment shown in FIG. 2F, the stored data bit SDT1 has a logic value 3. Correspondingly, each of the switch elements T1_1_95′-T1_9_95′ has the threshold voltage level HVT and is turned off, and each of the switch elements T1_1_95-T1_9_95 has the threshold voltage level LVT and is turned on.

At this moment, each of the memory strings MS1_1′-MS1_9′ has the resistance R, and each of the memory strings MS1_1-MS1_9′ has the resistance r. Alternatively stated, the memory block BK1 has 9 memory strings MS1_1-MS1_9′ with the resistance r, and the memory block BK1′ has 9 memory strings MS1_1′-MS1_9′ with the resistance R.

In summary, with the paired 9 sub-blocks SBK1_9-SBK1_9 and 9 sub-blocks SBK1_9′-SBK1_9′, the memory device 200 can perform Euclidean computing of 4-levels (that is, the logic values 0, 1, 2 and 3). However, the embodiments of present disclosure are not limited to this. In various embodiments, the memory device 200 can perform Euclidean computing of various quantities of levels. For example, in some embodiments, the memory device 200 can include paired 16 sub-blocks, to perform Euclidean computing of 5-levels (that is, the logic values 0, 1, 2, 3 and 4).

FIG. 3 is a schematic diagram 300 of the memory device 200 shown in FIG. 2A performing pseudo-Euclidean computing of 4-levels to the input bit IBT1, illustrated according to some embodiments of present disclosure.

As shown in the schematic diagram 300, when the input bit IBT1 has the logic value 0 or the logic value 1, the input bit IBT1 has an encoded value 0. When the input bit IBT1 has the logic value 2 or the logic value 3, the input bit IBT1 has an encoded value 3. Furthermore, the input bit IBT1 also can have a wildcard encoded value.

Referring to FIG. 2A to FIG. 3, the string select signals SSL and SSL′ can carry the input bit IBT1. When the input bit IBT1 has the encoded value 0, the string select signals SSL and SSL′ have the voltage levels HVSSL and LVSSL, respectively, such that each of the switch elements TS1_1-TS1_9 is turned on, and each of the switch elements TS1_1′-TS1_9′ is turned off.

When the input bit IBT1 has the encoded value 3, the string select signals SSL and SSL′ have the voltage levels LVSSL and HVSSL, respectively, such that each of the switch elements TS1_1-TS1_9 is turned off, and each of the switch elements TS1_1′-TS1_9′ is turned on.

When the input bit IBT1 has the wildcard encoded value, each of the string select signals SSL and SSL′ has the voltage level LVSSL, such that each of the switch elements TS1_1-TS1_9 and TS1_1′-TS1_9′ is turned off. In some embodiments, the wildcard encoded value is configured for highly matching. At this moment, the current signals generated by the memory blocks BK1 and BK1′ have the zero voltage level.

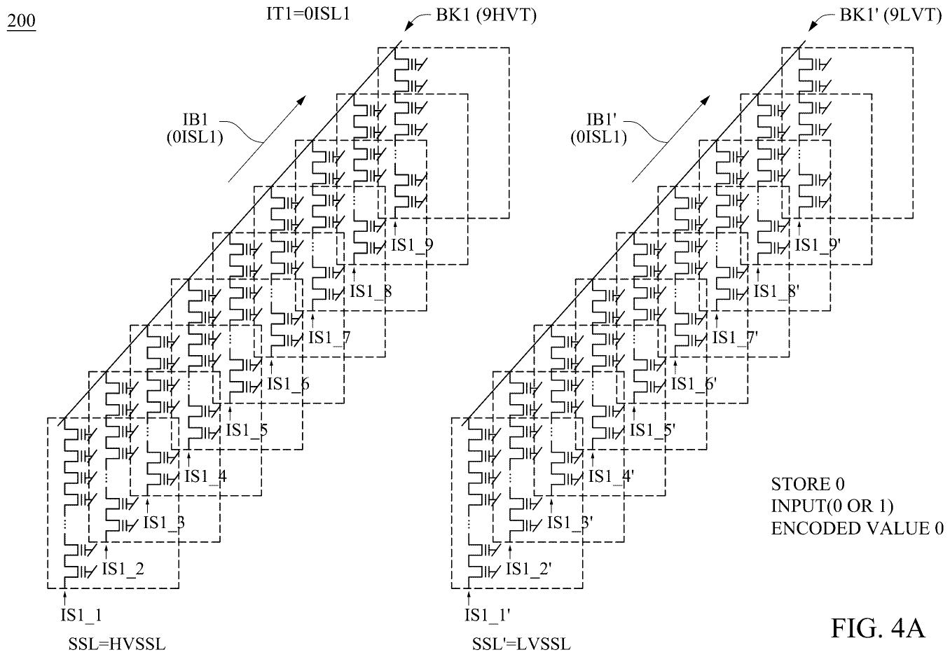

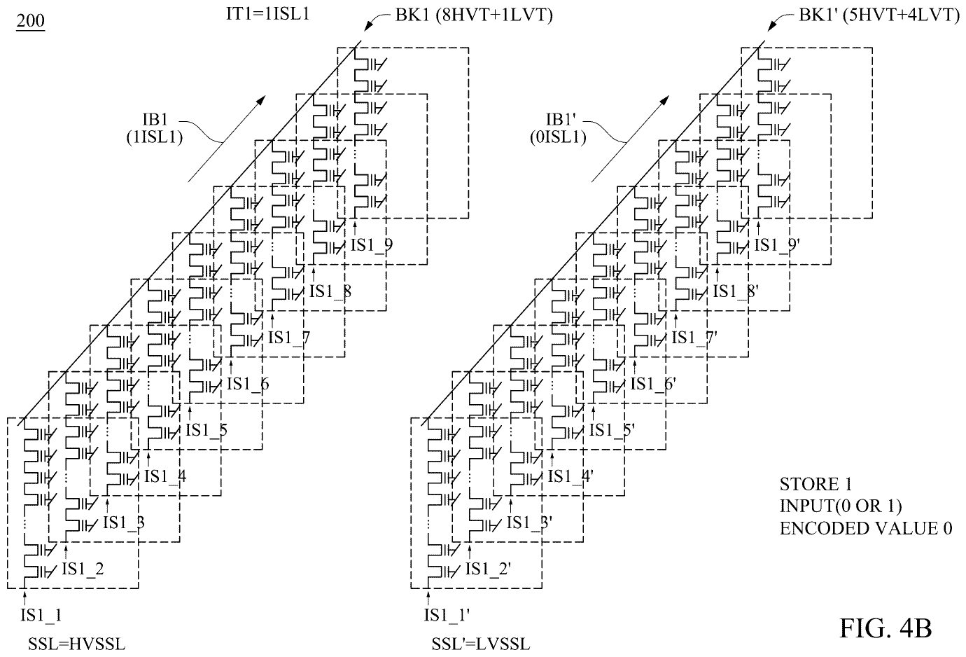

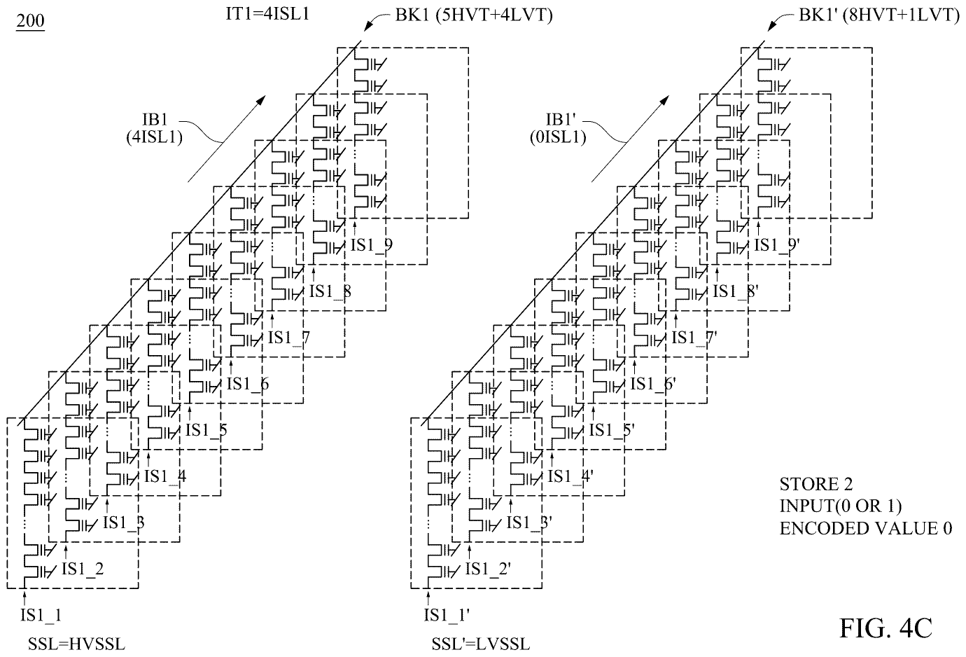

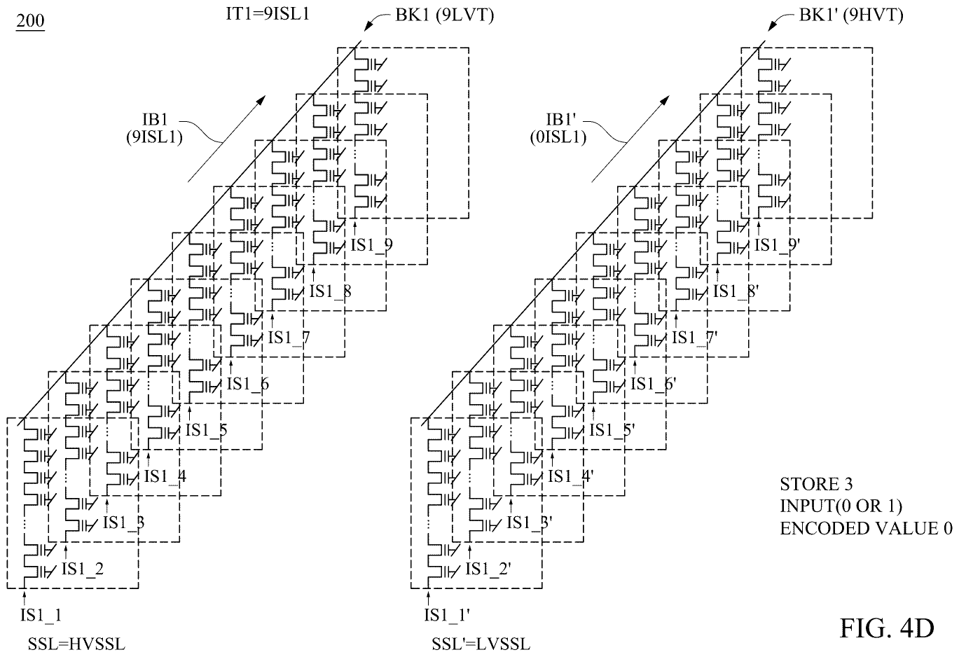

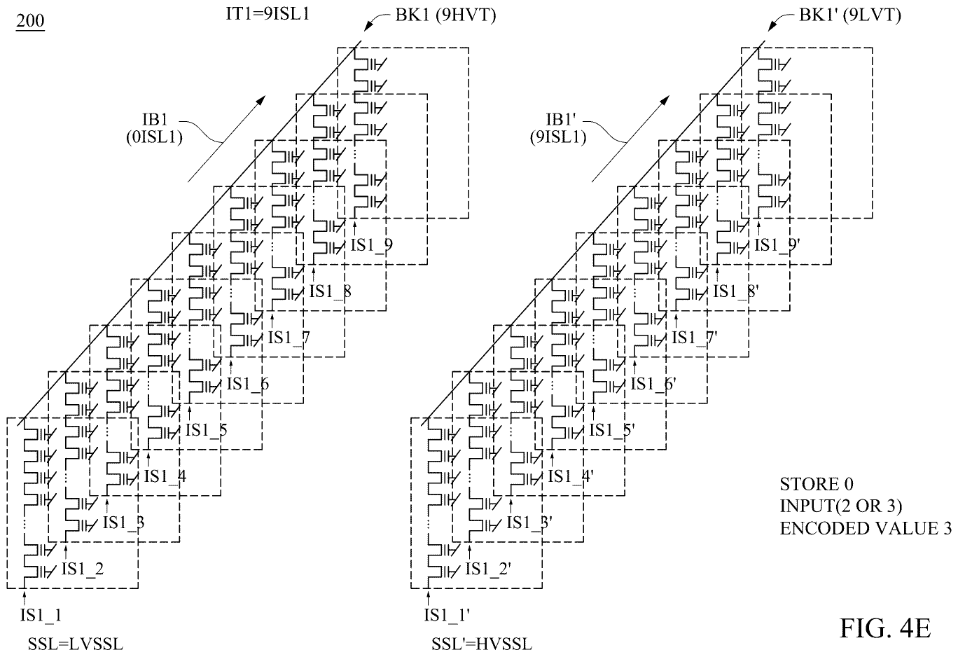

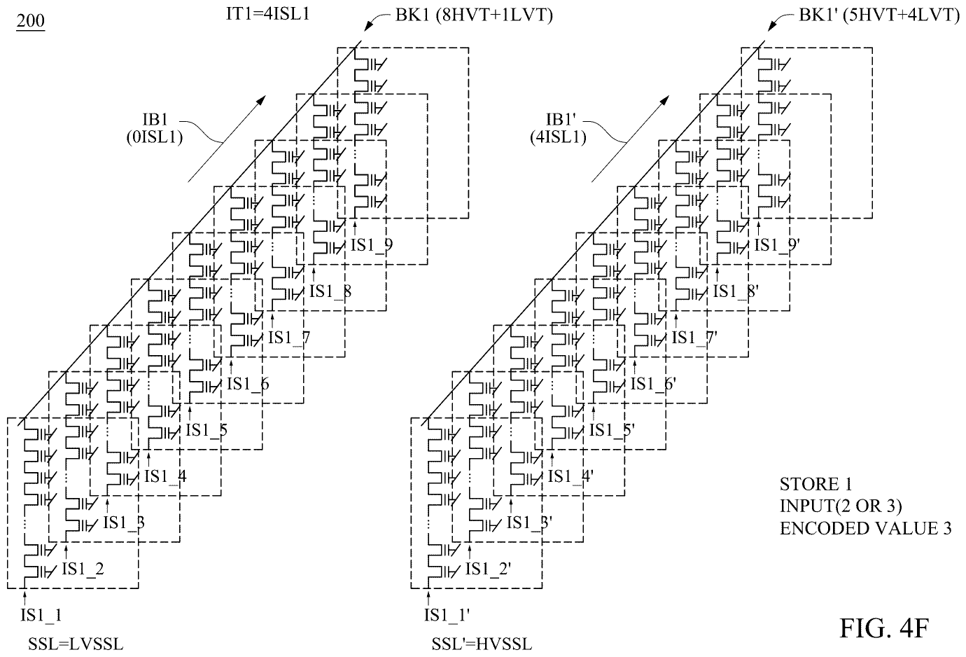

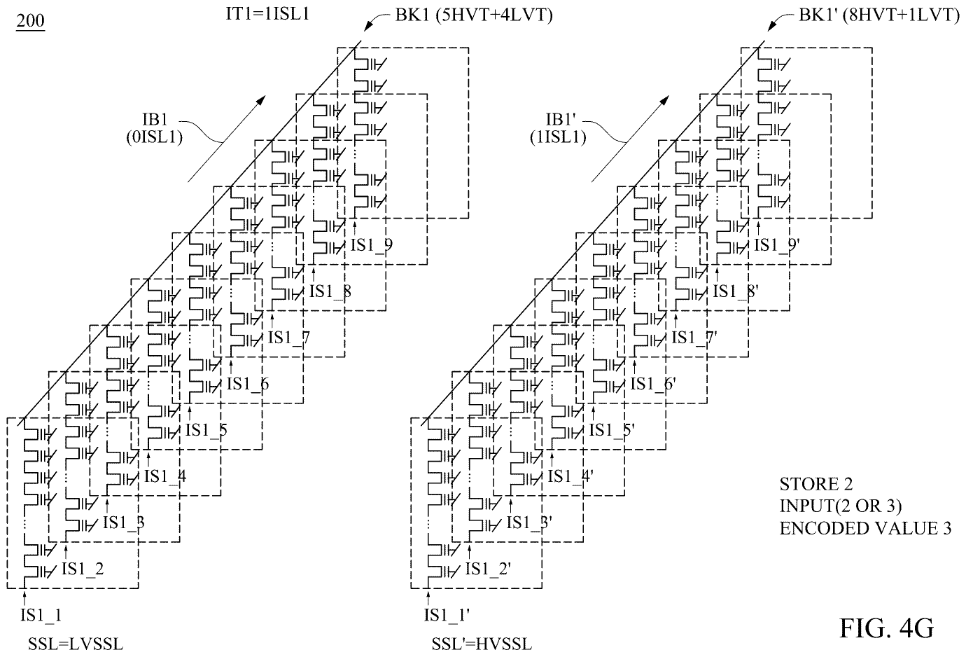

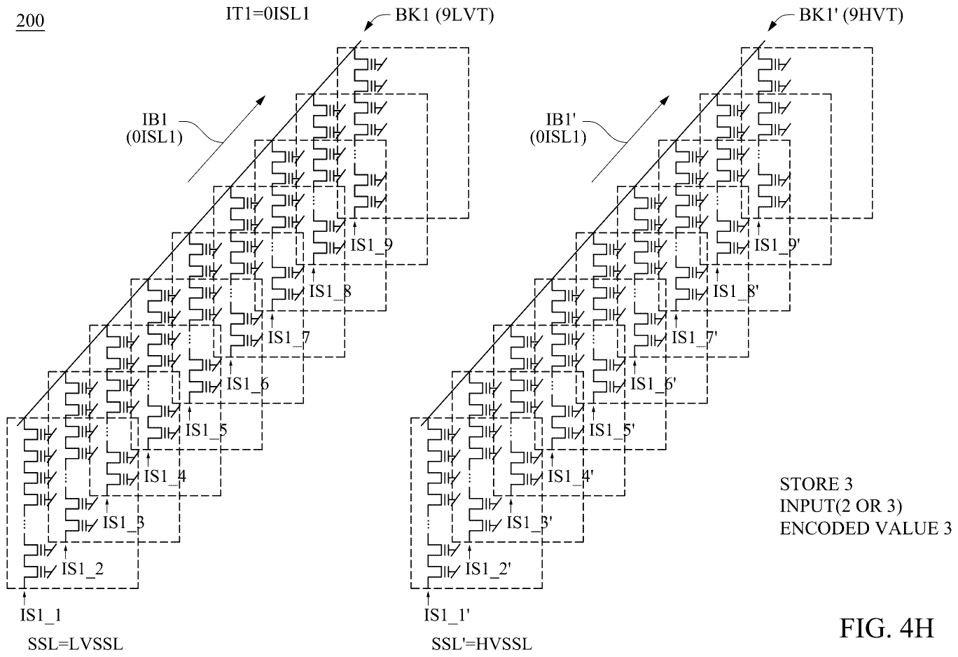

FIG. 4A is a schematic diagram of the memory device 200 performing the search operation, illustrated according to some embodiments of present disclosure. Referring to FIG. 2A to FIG. 4A, the embodiment shown FIG. 4A is an alternative embodiment of the embodiments shown in FIG. 2A to FIG. 2F. Therefore, for brevity, some descriptions are not repeated, and some labels are not shown in FIG. 4A. For example, the labels of the memory strings and some switch elements are not shown in FIG. 4A.

During the search operation, the memory device 200 is configured to compare the input bit IBT1 and the stored data bit SDT1, such that the memory strings MS1_1-MS1_9 generate string current signals IS1_1-IS1_9, respectively, and the memory strings MS1_1′-MS1_9′ generate string current signals IS1_1′-IS1_9′, respectively.

In some embodiments, the memory block BK1 is configured to sum the memory strings MS1_1-MS1_9 to generate a current signal IB1. The memory block BK1′ is configured to sum the memory strings MS1_1′-MS1_9′ to generate a current signal IB1′. In some embodiments, the memory device 200 is configured to sum the current signals IB1 and IB1′ to generate a current signal IT1.

Alternatively stated, a current level of the current signal IB1 is equal to a summation of current levels of the string current signals IS1_1-IS1_9, and a current level of the current signal IB1′ is equal to a summation of current levels of the string current signals IS1_1′-IS1_9′. A current level of the current signal IT1 is equal to a summation of the current levels of the current signals IB1 and IB1′.

In the embodiment shown in FIG. 4A, the input bit IBT1 has the logic value 0 or 1, and thus has the encoded value 0. Correspondingly, the string select line signals SSL and SSL′ has the voltage levels HVSSL and LVSSL, respectively, such that each of the switch elements TS1_1-TS1_9 is turned on, and each of the switch elements TS1_1′-TS1_9′ is turned off.

On the other hand, the stored data bit SDT1 has the logic value 0. Correspondingly, each of the switch elements T1_1_95-T1_9_95 has the threshold voltage level HVT, and each of the switch elements T1_1_95′-T1_9_95′ has the threshold voltage level LVT.

In response to the switch elements TS1_1′-TS1_9′ being turned off, each of the string current signals IS1_1′-IS1_9′ has the current level ISL2. In response to each of the switch elements T1_1_95-T1_9_95 having the threshold voltage level HVT, each of the string current signals IS1_1-IS1_9 has the current level ISL2.

Alternatively stated, each of the current levels of the current signals IB1 and IB1′ is equal to the current level ISL1 multiplied by 0. Correspondingly, a current level of the current signal IT1 is equal to the current level ISL1 multiplied by 0.

FIG. 4B is a schematic diagram of another condition of the memory device 200 performing the search operation, illustrated according to some embodiments of present disclosure. Referring to FIG. 4B and FIG. 4A, the embodiment shown FIG. 4B is an alternative embodiment of the embodiments shown in FIG. 4A. Therefore, for brevity, some descriptions are not repeated.

In the embodiment shown in FIG. 4B, the input bit IBT1 has the logic value 0 or 1, and thus has the encoded value 0. Correspondingly, the string select line signals SSL and SSL′ has the voltage levels HVSSL and LVSSL, respectively, such that each of the switch elements TS1_1-TS1_9 is turned on, and each of the switch elements TS1_1′-TS1_9′ is turned off.

On the other hand, the stored data bit SDT1 has the logic value 1. Correspondingly, each of the switch elements T1_2_95-T1_9_95 and T1_5_95′-T1_9_95′ has the threshold voltage level HVT, and each of the switch elements T1_1_95 and T1_4_95′-T1_9_95′ has the threshold voltage level LVT.

In response to the switch elements TS1_1′-TS1_9′ being turned off, each of the string current signals IS1_1′-IS1_9′ has the current level ISL2. In response to each of the switch elements T1_2_95-T1_9_95 having the threshold voltage level HVT, each of the string current signals IS1_2-IS1_9 has the current level ISL2. In response to the switch elements T1_1_95 having the threshold voltage level LVT and the switch element TS1_1 is turned on, the string current signal IS1_1 has the current level ISL1.

Alternatively stated, the current level of the current signals IB1 is equal to the current level ISL1 multiplied by 1, and the current level of the current signal IB1′ is equal to the current level ISL1 multiplied by 0. Correspondingly, a current level of the current signal IT1 is equal to the current level ISL1 multiplied by 1.

FIG. 4C is a schematic diagram of another condition of the memory device 200 performing the search operation, illustrated according to some embodiments of present disclosure. Referring to FIG. 4C and FIG. 4A, the embodiment shown FIG. 4C is an alternative embodiment of the embodiments shown in FIG. 4A. Therefore, for brevity, some descriptions are not repeated.

In the embodiment shown in FIG. 4C, the input bit IBT1 has the logic value 0 or 1, and thus has the encoded value 0. Correspondingly, the string select line signals SSL and SSL′ has the voltage levels HVSSL and LVSSL, respectively, such that each of the switch elements TS1_1-TS1_9 is turned on, and each of the switch elements TS1_1′-TS1_9′ is turned off.

On the other hand, the stored data bit SDT1 has the logic value 2. Correspondingly, each of the switch elements T1_5_95-T1_9_95 and T1_2_95′-T1_9_95′ has the threshold voltage level HVT, and each of the switch elements T1_1_95-T1_4_95 and T1_1_95′ has the threshold voltage level LVT.

In response to the switch elements TS1_1′-TS1_9′ being turned off, each of the string current signals IS1_1′-IS1_9′ has the current level ISL2. In response to each of the switch elements T1_5_95-T1_9_95 having the threshold voltage level HVT, each of the string current signals IS1_5-IS1_9 has the current level ISL2. In response to each of the switch elements T1_1_95-T1_4_95 having the threshold voltage level LVT and each of the switch elements TS1_1-TS1_4 is turned on, each of the string current signals IS1_1-IS1_4 has the current level ISL1.

Alternatively stated, the current level of the current signals IB1 is equal to the current level ISL1 multiplied by 4, and the current level of the current signal IB1′ is equal to the current level ISL1 multiplied by 0. Correspondingly, a current level of the current signal IT1 is equal to the current level ISL1 multiplied by 4.

FIG. 4D is a schematic diagram of another condition of the memory device 200 performing the search operation, illustrated according to some embodiments of present disclosure. Referring to FIG. 4D and FIG. 4A, the embodiment shown FIG. 4D is an alternative embodiment of the embodiments shown in FIG. 4A. Therefore, for brevity, some descriptions are not repeated.

In the embodiment shown in FIG. 4D, the input bit IBT1 has the logic value 0 or 1, and thus has the encoded value 0. Correspondingly, the string select line signals SSL and SSL′ has the voltage levels HVSSL and LVSSL, respectively, such that each of the switch elements TS1_1-TS1_9 is turned on, and each of the switch elements TS1_1′-TS1_9′ is turned off.

On the other hand, the stored data bit SDT1 has the logic value 3. Correspondingly, each of the switch elements and T1_1_95′-T1_9_95′ has the threshold voltage level HVT, and each of the switch elements T1_1_95-T1_9_95 has the threshold voltage level LVT.

In response to the switch elements TS1_1′-TS1_9′ being turned off, each of the string current signals IS1_1′-IS1_9′ has the current level ISL2. In response to each of the switch elements T1_1_95-T1_9_95 having the threshold voltage level LVT and each of the switch elements TS1_1-TS1_9 is turned on, each of the string current signals IS1_1-IS1_9 has the current level ISL1.

Alternatively stated, the current level of the current signals IB1 is equal to the current level ISL1 multiplied by 9, and the current level of the current signal IB1′ is equal to the current level ISL1 multiplied by 0. Correspondingly, a current level of the current signal IT1 is equal to the current level ISL1 multiplied by 9.

FIG. 4E is a schematic diagram of another condition of the memory device 200 performing the search operation, illustrated according to some embodiments of present disclosure. Referring to FIG. 4E and FIG. 4A, the embodiment shown FIG. 4E is an alternative embodiment of the embodiments shown in FIG. 4A. Therefore, for brevity, some descriptions are not repeated.

In the embodiment shown in FIG. 4E, the input bit IBT1 has the logic value 2 or 3, and thus has the encoded value 3. Correspondingly, the string select line signals SSL and SSL′ has the voltage levels LVSSL and HVSSL, respectively, such that each of the switch elements TS1_1-TS1_9 is turned off, and each of the switch elements TS1_1′-TS1_9′ is turned on.

On the other hand, the stored data bit SDT1 has the logic value 0. Correspondingly, each of the switch elements and T1_1_95-T1_9_95 has the threshold voltage level HVT, and each of the switch elements T1_1_95′-T1_9_95′ has the threshold voltage level LVT.

In response to the switch elements TS1_1-TS1_9 being turned off, each of the string current signals IS1_1-IS1_9 has the current level ISL2. In response to each of the switch elements T1_1_95′-T1_9_95′ having the threshold voltage level LVT and each of the switch elements TS1_1′-TS1_9′ is turned on, each of the string current signals IS1_1′-IS1_9′ has the current level ISL1.

Alternatively stated, the current level of the current signals IB1 is equal to the current level ISL1 multiplied by 0, and the current level of the current signal IB1′ is equal to the current level ISL1 multiplied by 9. Correspondingly, a current level of the current signal IT1 is equal to the current level ISL1 multiplied by 9.

FIG. 4F is a schematic diagram of another condition of the memory device 200 performing the search operation, illustrated according to some embodiments of present disclosure. Referring to FIG. 4F and FIG. 4A, the embodiment shown FIG. 4F is an alternative embodiment of the embodiments shown in FIG. 4A. Therefore, for brevity, some descriptions are not repeated.

In the embodiment shown in FIG. 4F, the input bit IBT1 has the logic value 2 or 3, and thus has the encoded value 3. Correspondingly, the string select line signals SSL and SSL′ has the voltage levels LVSSL and HVSSL, respectively, such that each of the switch elements TS1_1-TS1_9 is turned off, and each of the switch elements TS1_1′-TS1_9′ is turned on.

On the other hand, the stored data bit SDT1 has the logic value 1. Correspondingly, each of the switch elements and T1_2_95-T1_9_95 and T1_5_95′-T1_9_95′ has the threshold voltage level HVT, and each of the switch elements T1_1_95 and T1_1_95′-T1_4_95′ has the threshold voltage level LVT.

In response to the switch elements TS1_1-TS1_9 being turned off, each of the string current signals IS1_1-IS1_9 has the current level ISL2. In response to each of the switch elements T1_5_95′-T1_9_95′ having the threshold voltage level HVT, each of the string current signals IS1_5′-IS1_9′ has the current level ISL2. In response to each of the switch elements T1_1_95′-T1_4_95′ having the threshold voltage level LVT and each of the switch elements TS1_1′-TS1_4′ is turned on, each of the string current signals IS1_1′-IS1_4′ has the current level ISL1.

Alternatively stated, the current level of the current signals IB1 is equal to the current level ISL1 multiplied by 0, and the current level of the current signal IB1′ is equal to the current level ISL1 multiplied by 4. Correspondingly, a current level of the current signal IT1 is equal to the current level ISL1 multiplied by 4.

FIG. 4G is a schematic diagram of another condition of the memory device 200 performing the search operation, illustrated according to some embodiments of present disclosure. Referring to FIG. 4G and FIG. 4A, the embodiment shown FIG. 4G is an alternative embodiment of the embodiments shown in FIG. 4A. Therefore, for brevity, some descriptions are not repeated.

In the embodiment shown in FIG. 4G, the input bit IBT1 has the logic value 2 or 3, and thus has the encoded value 3. Correspondingly, the string select line signals SSL and SSL′ has the voltage levels LVSSL and HVSSL, respectively, such that each of the switch elements TS1_1-TS1_9 is turned off, and each of the switch elements TS1_1′-TS1_9′ is turned on.

On the other hand, the stored data bit SDT1 has the logic value 2. Correspondingly, each of the switch elements and T1_5_95-T1_9_95 and T1_2_95′-T1_9_95′ has the threshold voltage level HVT, and each of the switch elements T1_1_95-T1_4_95 and T1_1_95′ has the threshold voltage level LVT.

In response to the switch elements TS1_1-TS1_9 being turned off, each of the string current signals IS1_1-IS1_9 has the current level ISL2. In response to each of the switch elements T1_2_95′-T1_9_95′ having the threshold voltage level HVT, each of the string current signals IS1_2′-IS1_9′ has the current level ISL2. In response to the switch element T1_1_95′ having the threshold voltage level LVT and the switch element TS1_1′ is turned on, the string current signal IS1_1′ has the current level ISL1.

Alternatively stated, the current level of the current signals IB1 is equal to the current level ISL1 multiplied by 0, and the current level of the current signal IB1′ is equal to the current level ISL1 multiplied by 1. Correspondingly, a current level of the current signal IT1 is equal to the current level ISL1 multiplied by 1.

FIG. 4H is a schematic diagram of another condition of the memory device 200 performing the search operation, illustrated according to some embodiments of present disclosure. Referring to FIG. 4H and FIG. 4A, the embodiment shown FIG. 4H is an alternative embodiment of the embodiments shown in FIG. 4A. Therefore, for brevity, some descriptions are not repeated.

In the embodiment shown in FIG. 4H, the input bit IBT1 has the logic value 2 or 3, and thus has the encoded value 3. Correspondingly, the string select line signals SSL and SSL′ has the voltage levels LVSSL and HVSSL, respectively, such that each of the switch elements TS1_1-TS1_9 is turned off, and each of the switch elements TS1_1′-TS1_9′ is turned on.

On the other hand, the stored data bit SDT1 has the logic value 3. Correspondingly, each of the switch elements and T1_1_95′-T1_9_95′ has the threshold voltage level HVT, and each of the switch elements T1_1_95-T1_9_95 has the threshold voltage level LVT.

In response to the switch elements TS1_1-TS1_9 being turned off, each of the string current signals IS1_1-IS1_9 has the current level ISL2. In response to each of the switch elements T1_1_95′-T1_9_95′ having the threshold voltage level HVT, each of the string current signals IS1_1′-IS1_9′ has the current level ISL2.

Alternatively stated, the current level of the current signals IB1 is equal to the current level ISL1 multiplied by 0, and the current level of the current signal IB1′ is equal to the current level ISL1 multiplied by 0. Correspondingly, a current level of the current signal IT1 is equal to the current level ISL1 multiplied by 0.

In summary, the current level of the current signal IT1 is proportional to a square of a difference between the encoded value of the input bit IBT1 and the logic value of the stored data bit SDT1.

For example, in the embodiment shown in FIG. 4A, a difference 0 is between the encoded value 0 of the input bit IBT1 and the logic value 0 of the stored data bit SDT1. In the embodiment shown in FIG. 4H, the difference 0 is between the encoded value 3 of the input bit IBT1 and the logic value 3 of the stored data bit SDT1. Correspondingly, in the two conditions described above, the current level of the current signal IT1 is proportional to a square of 0, that is, the current level ISL1 multiplied by 0.

In the embodiment shown in FIG. 4B, a difference 1 is between the encoded value 0 of the input bit IBT1 and the logic value 1 of the stored data bit SDT1. In the embodiment shown in FIG. 4G, the difference 1 is between the encoded value 3 of the input bit IBT1 and the logic value 2 of the stored data bit SDT1. Correspondingly, in the two conditions described above, the current level of the current signal IT1 is proportional to a square of 1, that is, the current level ISL1 multiplied by 1.

In the embodiment shown in FIG. 4C, a difference 2 is between the encoded value 0 of the input bit IBT1 and the logic value 2 of the stored data bit SDT1. In the embodiment shown in FIG. 4F, the difference 2 is between the encoded value 3 of the input bit IBT1 and the logic value 1 of the stored data bit SDT1. Correspondingly, in the two conditions described above, the current level of the current signal IT1 is proportional to a square of 2, that is, the current level ISL1 multiplied by 4.

In the embodiment shown in FIG. 4D, a difference 3 is between the encoded value 0 of the input bit IBT1 and the logic value 3 of the stored data bit SDT1. In the embodiment shown in FIG. 4E, the difference 3 is between the encoded value 3 of the input bit IBT1 and the logic value 0 of the stored data bit SDT1. Correspondingly, in the two conditions described above, the current level of the current signal IT1 is proportional to a square of 3, that is, the current level ISL1 multiplied by 9.

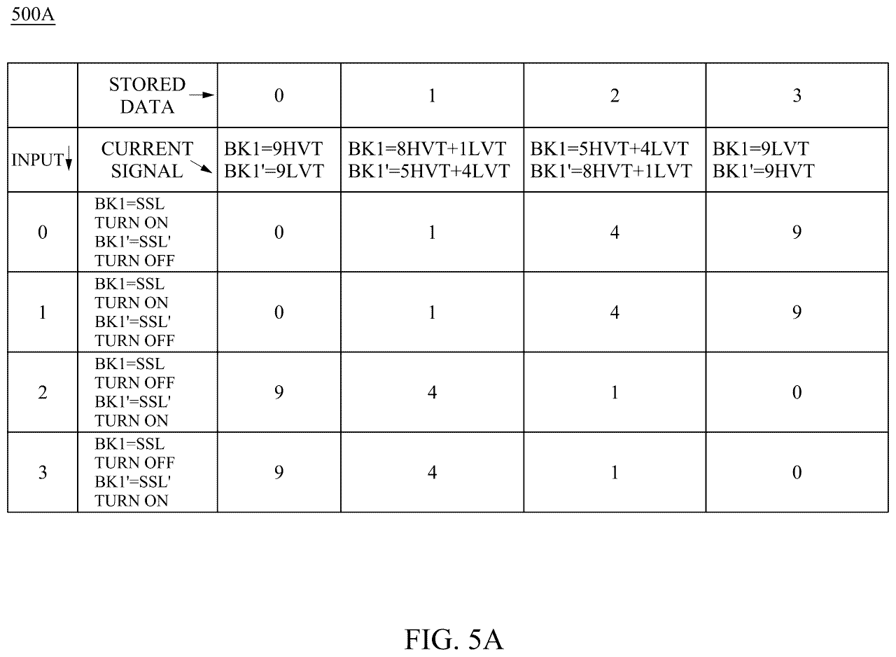

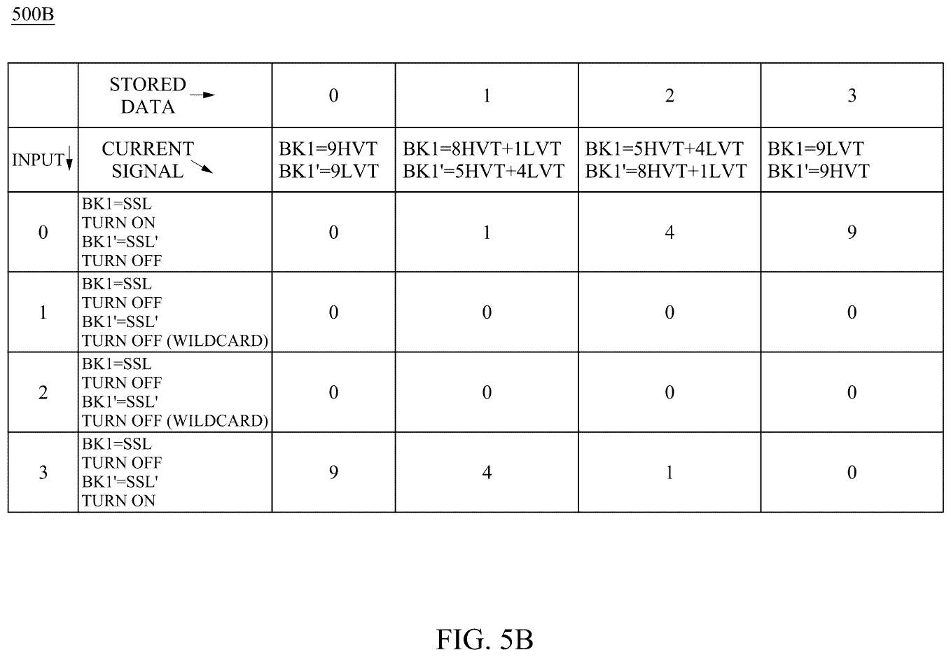

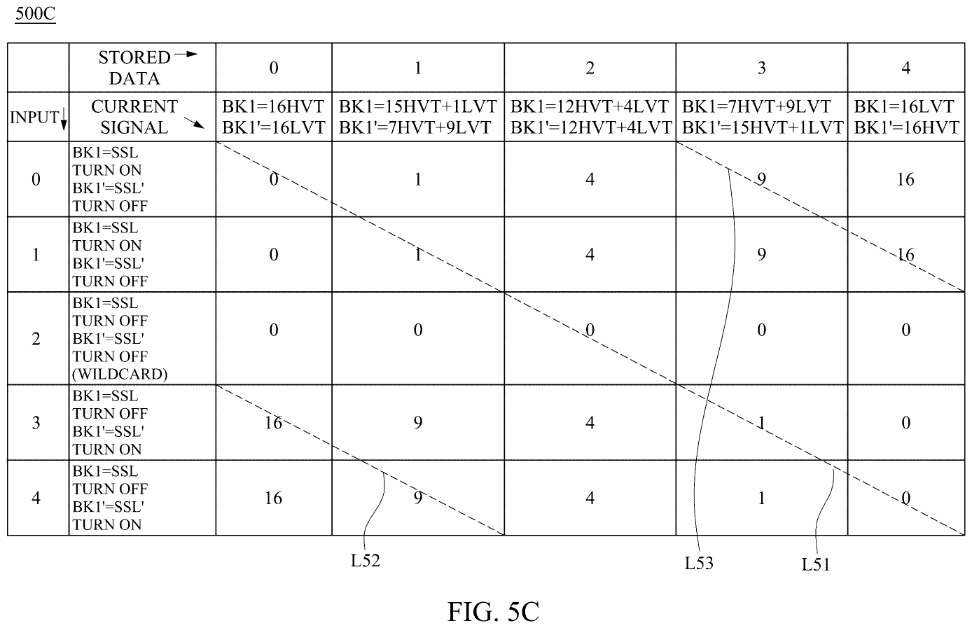

FIG. 5A is a table 500A of the memory device 200 performing the search operation, illustrated according to some embodiments of present disclosure. As shown in the table 500A, when the input bit IBT1 has the logic value 0 or 1, the switch elements TS1_1-TS1_9 in the memory block BK1 are turned on by the string select line signal SSL, and the switch elements TS1_1′-TS1_9′ in the memory block BK1′ are turned off by the string select line signal SSL′. When the input bit IBT1 has the logic value 2 or 3, the switch elements TS1_1-TS1_9 in the memory block BK1 are turned off by the string select line signal SSL, and the switch elements TS1_1′-TS1_9′ in the memory block BK1′ are turned on by the string select line signal SSL′.

On the other hand, when the stored data bit SDT1 has the logic value 0, the memory block BK1 has 9 switch elements having the threshold voltage level HVT, and the memory block BK1′ has 9 switch elements having the threshold voltage level LVT.

When the stored data bit SDT1 has the logic value 1, the memory block BK1 has 8 switch elements having the threshold voltage level HVT and 1 switch element having the threshold voltage level LVT, and the memory block BK1′ has 5 switch elements having the threshold voltage level HVT and 4 switch elements having the threshold voltage level LVT.

When the stored data bit SDT1 has the logic value 2, the memory block BK1 has 5 switch elements having the threshold voltage level HVT and 4 switch elements having the threshold voltage level LVT, and the memory block BK1′ has 8 switch elements having the threshold voltage level HVT and 1 switch element having the threshold voltage level LVT.

When the stored data bit SDT1 has the logic value 3, the memory block BK1 has 9 switch elements having the threshold voltage level LVT, and the memory block BK1′ has 9 switch elements having the threshold voltage level HVT.

As shown in FIG. 5A, in different conditions, the current signal IT1 has different current levels. In the conditions those the input bit IBT1 has the logic value 0 or 1, in response the stored data bit SDT1 having the logic values 0-3, the current level of the current signal IT1 is equal to the current level ISL1 multiplied by 0, 1, 4 and 9, respectively. In the conditions those the input bit IBT1 has the logic value 2 or 3, in response the stored data bit SDT1 having the logic values 0-3, the current level of the current signal IT1 is equal to the current level ISL1 multiplied by 9, 4, 1 and 0, respectively.

In the embodiment shown in FIG. 5A, the memory device 200 operates without the wildcard encoded value. In other embodiments, the memory device 200 operates without the wildcard encoded value, such as the embodiment shown in FIG. 5B described following.

FIG. 5B is a table 500B of the memory device 200 performing the search operation, illustrated according to some embodiments of present disclosure. Referring to FIG. 5A and FIG. 5B, the table 500B is an alternative embodiment of the table 500A. Therefore, for brevity, some descriptions are not repeated.

Compared to the table 500A, in the embodiment of the table 500B, when the input bit IBT1 has the logic value 1 or the logic value 2, the input bit IBT1 has the wildcard encoded value. Referring to FIG. 3 and FIG. 5B, when the input bit IBT1 has the wildcard encoded value, each of the string select line signals SSL and SSL′ has the voltage level LVSSL, such that corresponding switch elements are turned off.

Alternatively stated, when the input bit IBT1 has the logic value 1 or 2, the switch elements TS1_1-TS1_9 in the memory block BK1 are turned off by the string select line signal SSL, and the switch elements TS1_1′-TS1_9′ in the memory block BK1 are turned off by the string select line signal SSL′.

Correspondingly, in the conditions those the input bit IBT1 having the logic value 1 or 2, in response the stored data bit SDT1 having the logic values 0-3, the current level of the current signal IT1 is equal to the current level ISL1 multiplied by 0.

FIG. 5C is a table 500C of the memory device 200 performing the search operation, illustrated according to some embodiments of present disclosure. Referring to FIG. 5B and FIG. 5C, the table 500C is an alternative embodiment of the table 500B. Therefore, for brevity, some descriptions are not repeated.

In the embodiment shown in FIG. 5C, the memory cell has 5 levels. Alternatively stated, each of the input bit IBT1 and the stored data bit SDT1 can have the logic values 0-4. Referring to FIG. 4A to FIG. 5C, when the memory cell has 5 levels, each of the memory blocks BK1 and BK1′ includes 16 memory strings, to store the logic values 0-4.

When the stored data bit SDT1 has the logic value 0, the memory block BK1 includes 16 switch elements having the threshold voltage level HVT, and the memory block BK1′ includes 16 switch elements having the threshold voltage level LVT.

When the stored data bit SDT1 has the logic value 1, the memory block BK1 includes 15 switch elements having the threshold voltage level HVT and 1 switch element having the threshold voltage level LVT, and the memory block BK1′ includes 7 switch elements having the threshold voltage level HVT and 9 switch elements having the threshold voltage level LVT.

When the stored data bit SDT1 has the logic value 2, the memory block BK1 includes 12 switch elements having the threshold voltage level HVT and 4 switch element having the threshold voltage level LVT, and the memory block BK1′ includes 12 switch elements having the threshold voltage level HVT and 4 switch elements having the threshold voltage level LVT.

When the stored data bit SDT1 has the logic value 3, the memory block BK1 includes 7 switch elements having the threshold voltage level HVT and 9 switch element having the threshold voltage level LVT, and the memory block BK1′ includes 15 switch elements having the threshold voltage level HVT and 1 switch elements having the threshold voltage level LVT.

When the stored data bit SDT1 has the logic value 4, the memory block BK1 includes 16 switch elements having the threshold voltage level LVT, and the memory block BK1′ includes 16 switch elements having the threshold voltage level HVT.

On the other hand, when the input bit IBT1 has the logic value 0 or 1, switch elements in the memory block BK1 are turned on by the string select line signal SSL, and switch elements in the memory block BK1′ are turned off by the string select line signal SSL′. When the input bit IBT1 has the logic value 2, the switch elements in the memory blocks BK1 and BK1′ are turned off by the string select line signals SSL and SSL′. When the input bit IBT1 has the logic value 3 or 4, the switch elements in the memory block BK1 are turned off by the string select line signal SSL, and the switch elements in the memory block BK1′ are turned on by the string select line signal SSL′.

Correspondingly, in the conditions those the input bit IBT1 has the logic value 0 or 1, in response the stored data bit SDT1 having the logic values 0-4, the current level of the current signal IT1 is equal to the current level ISL1 multiplied by 0, 1, 4, 9 and 16, respectively.

in the conditions those the input bit IBT1 has the logic value 2, in response the stored data bit SDT1 having the logic values 0-4, the current level of the current signal IT1 is equal to the current level ISL1 multiplied by 0. At this moment, the input bit IBT1 can be referred to as having the wildcard encoded value.

In the conditions those the input bit IBT1 has the logic value 3 or 4, in response the stored data bit SDT1 having the logic values 0-4, the current level of the current signal IT1 is equal to the current level ISL1 multiplied by 16, 9, 4, 1 and 0, respectively.

In summary, in various conditions of FIG. 5A to FIG. 5C, when the difference between the logic value of the input bit IBT1 and the logic value of the stored data bit SDT1 is larger, the current level of the current signal IT1 is larger. In contrast, when the difference between the logic value of the input bit IBT1 and the logic value of the stored data bit SDT1 is smaller, the current level of the current signal IT1 is smaller. As a result, with the memory device 200, pseudo-Euclidean computing can be achieved.

For example, in the embodiment shown in FIG. 5C, in the conditions along the line L51, the logic value of the input bit IBT1 is equal to the logic value of the stored data bit SDT1. Alternatively stated, the difference between the logic value of the input bit IBT1 and the logic value of the stored data bit SDT1 is equal to 0. Correspondingly, the current level of the current signal IT1 is equal to the current level ISL1 multiplied by 0 or 1. In the conditions along the lines L52 and L53, the difference between the logic value of the input bit IBT1 and the logic value of the stored data bit SDT1 is equal to 3. Correspondingly, the current level of the current signal IT1 is equal to the current level ISL1 multiplied by 9 or 16.

In some approaches, a memory device only uses two switch elements to store one stored data bit, and uses two word line signals to carry one input bit, such that the reliability and the robustness are lower, and the operation of the word line signals are complicated.

Compared to above approaches, in the embodiments of present disclosure, the memory device 200 stores the stored data bit SDT1 by a memory block pair BKP1, and carries the input bit IBT1 by two string select line signals SSL and SSL′, such that the reliability and the robustness are higher, and the operation of the string select line signals SSL and SSL′ are simple.

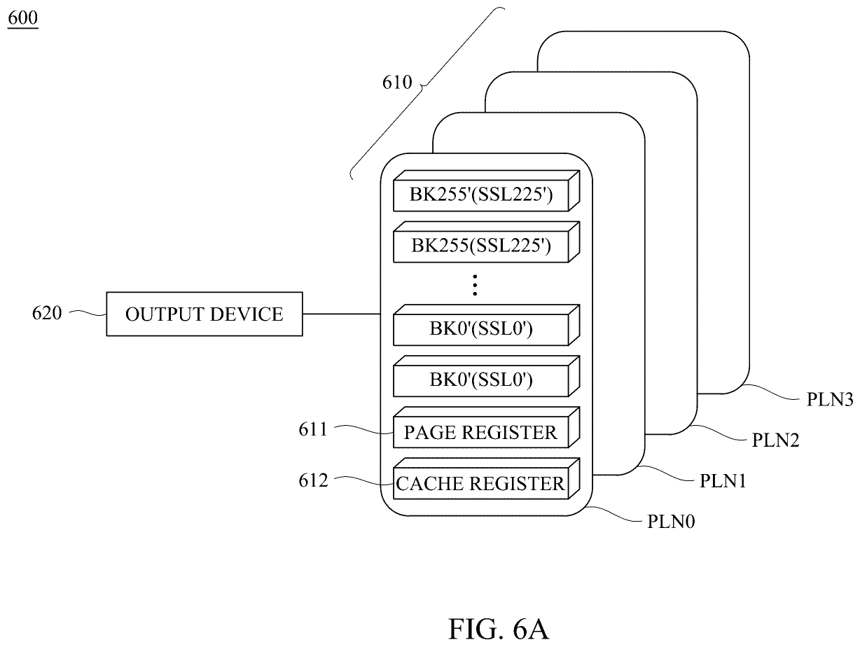

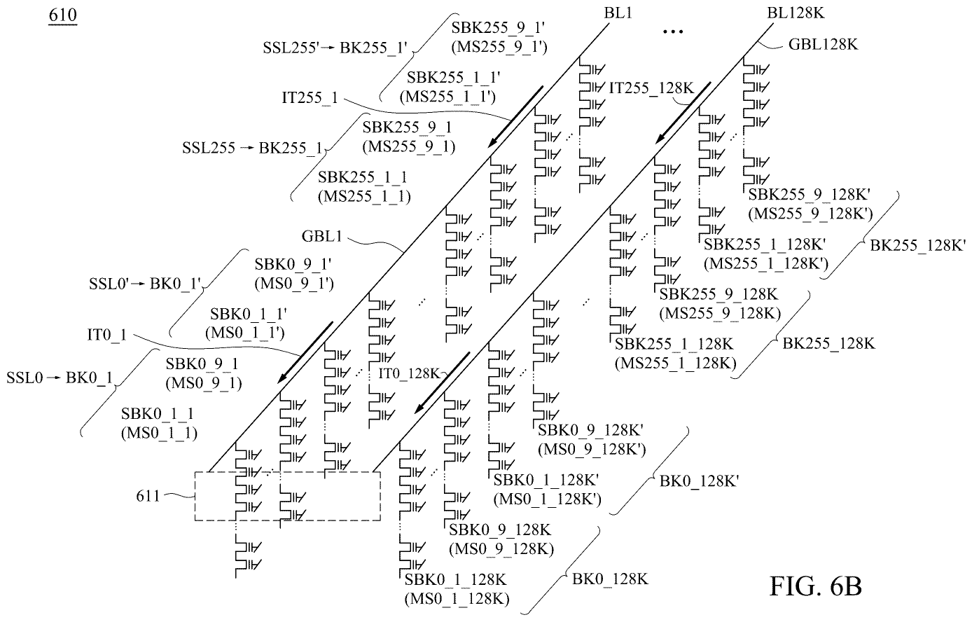

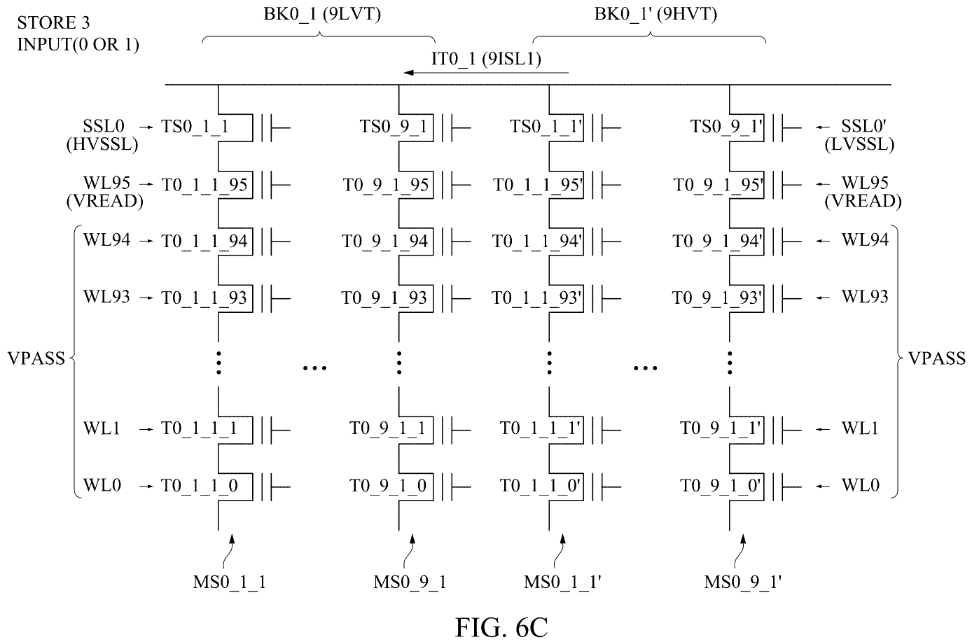

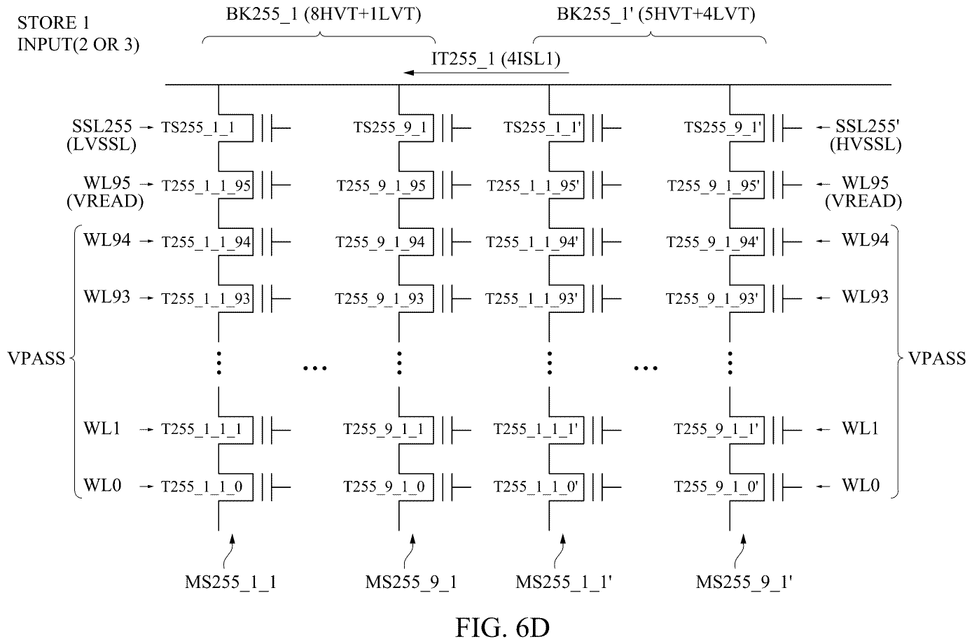

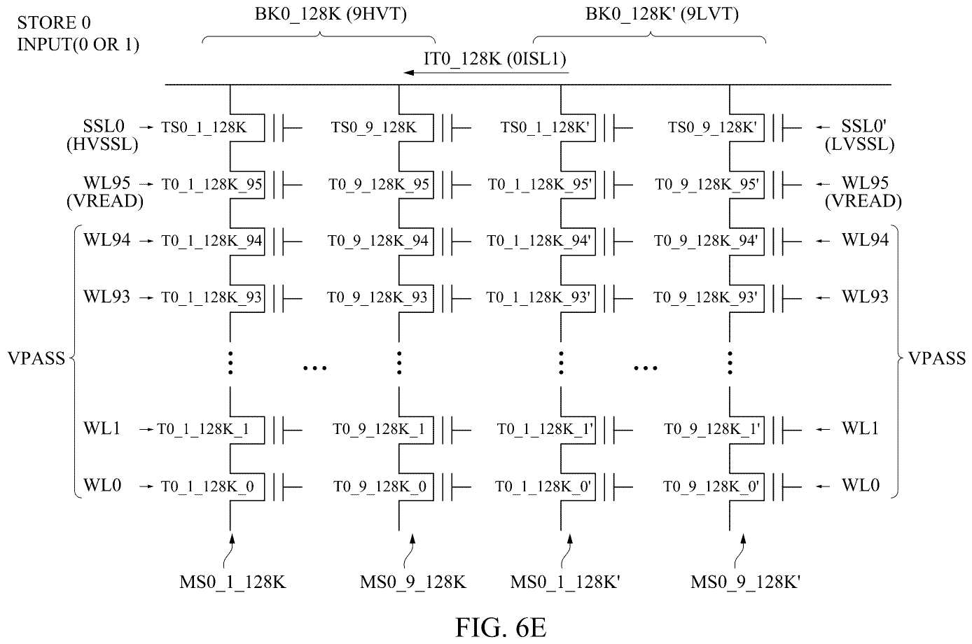

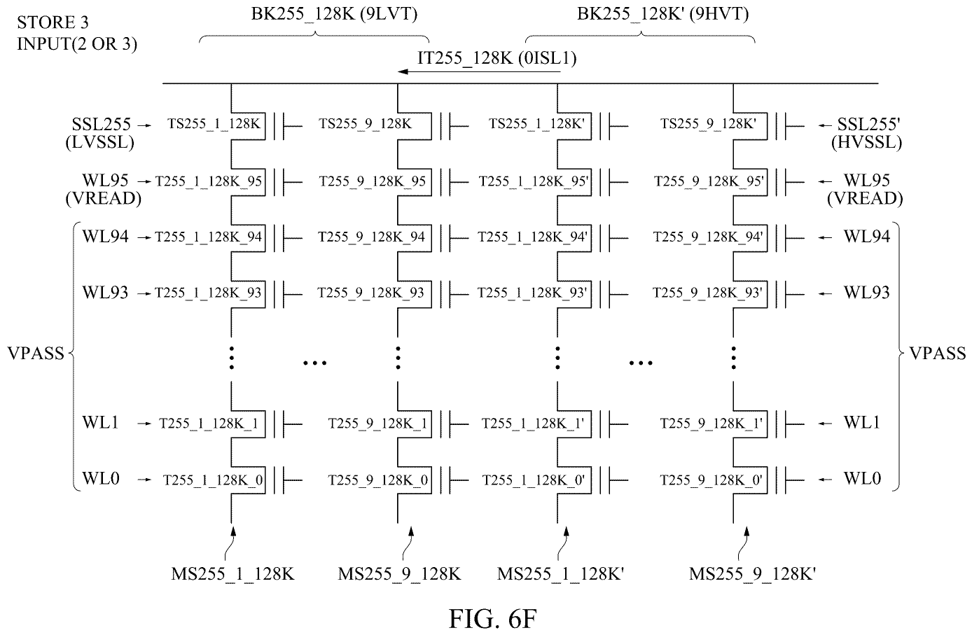

FIG. 6A is a schematic diagram of a memory system 600, illustrated according to some embodiments of present disclosure. As shown in FIG. 6A, the memory system 600 includes a memory device 610 and an output device 620. In some embodiments, the memory device 610 is configured to perform the search operation to generate corresponding bit line signals. The output device 620 is configured to output the matching results of the search operation of the memory device 610.

As shown in FIG. 6A, the memory device 610 includes multiple memory planes, such as the memory planes PLN0-PLN4. The memory plane includes multiple memory blocks, a page register and a cache register. For example, the memory plane PLN0 includes memory blocks BK0-BK255, BK0′-BK255′, a page register 611 and a cache register 612. However, the embodiments of present disclosure are not limited to this. In various embodiments, the memory device 610 can include various quantities of memory blocks, that is, 255 can be substituted with other positive integers.

In some embodiments, the page register 611 can be implemented by a sensing amplifier, and is configured to sense corresponding searching results of the bit line signals. The cache register 612 can process the bit line signals by processes including logic processes of AND logic, OR logic or counting, and also may including combining processes of the three logic processes described above. Referring to FIG. 1A to FIG. 6A, the cache register 612 can receive sense results from the memory device 100, 200 and/or the memory blocks BK0-BK255, BK0′-BK255′, and controls sequencing (whether serial or parallel) and combines sense results to produce overall search results as the matching results outputted from the output device 620.

In some embodiments, the cache register 612 can operate with a priority encoder (not shown in figures). The priority encoder can perform priority encoding to the corresponding searching results of the bit line signals. For example, the cache register 612 and the priority encoder collectively processes the corresponding searching results of the bit line signals, and preferentially select an address of a bit line signal corresponding to the best searching result (that is, an input value of input data and a stored value of stored data are closest to each other).

As shown in FIG. 6A, the memory blocks BK0-BK255, BK0′-BK255′ are configured to receive string select line signals SSL0-SSL255 and SSL0′-SSL255′, respectively. Referring to FIG. 2A to FIG. 6A, configurations of the string select line signals SSL0-SSL255 and SSL0′-SSL255′ are similar with the configurations string select line signals SSL and SSL′. Therefore, for brevity, some descriptions are not repeated.

FIG. 6B is a schematic diagram of further details of the memory device 610, illustrated according to some embodiments of present disclosure. As shown in FIG. 6B, the memory device 610 includes global bit lines GBL1-GBL128K, in which K is equal to a thousand. The global bit lines GBL1-GBL128K are respectively configured to transmit bit line signals BL1-BL128K to the page register 611. However, the embodiments of present disclosure are not limited to this. In various embodiments, the memory device 610 can include various quantities of global bit lines, that is, 128K can be substituted with other positive integers.

As shown in FIG. 6B, the memory device 610 further includes memory blocks BK0_1-BK255_1 and BK0_1′-BK255_1′ coupled to the global bit line GBL1. The memory blocks BK0_1 and BK0_1′ are configured to generate a current signal IT0_1. The memory blocks BK1_1 and BK1_1′ are configured to generate a current signal IT1_1, and so on. The memory blocks BK255_1 and BK0_1′ are configured to generate a current signal IT255_1.

Referring to FIG. 2A to FIG. 6A, configurations of the memory blocks BK0_1-BK255_1, BK0_1′-BK255_1′ and the current signals IT0_1-IT255_1 are similar with the configurations of the memory blocks BK1, BK1′ and the current signals IT1. Therefore, for brevity, some descriptions are not repeated.

In some embodiments, the memory device 610 is configured to sum the current signals IT0_1-IT255_1 on the global bit line GBL1 to generate a bit line signal BL1. Alternatively stated, a current level of the bit line signal BL1 is equal to a summation of the current levels of the current signals IT0_1-IT255_1.

As shown in FIG. 6A, the memory device 610 further includes memory blocks BK0_128K-BK255_128K and BK0_128K′-BK255_128K′ coupled to the global bit line GBL128K. The memory blocks BK0_128K and BK0_128K′ are configured to generate a current signal IT0_128K. The memory blocks BK1_128K and BK1_128K′ are configured to generate a current signal IT1_128K, and so on. The memory blocks BK255_128K and BK0_128K′ are configured to generate a current signal IT255_128K.

Referring to FIG. 2A to FIG. 6A, configurations of the memory blocks BK0_128K-BK255_128K, BK0_128K′-BK255_128K′ and the current signals IT0_128K-IT255_128K are similar with the configurations of the memory blocks BK1, BK1′ and the current signals IT1. Therefore, for brevity, some descriptions are not repeated.

In some embodiments, the memory device 610 is configured to sum the current signals IT0_128K-IT255_128K on the global bit line GBL128K to generate a bit line signal BL128K. Alternatively stated, a current level of the bit line signal BL128K is equal to a summation of the current levels of the current signals IT0_128K-IT255_128K.

Furthermore, the memory device 610 further includes multiple memory blocks coupled to the other global bit lines. These memory blocks generate corresponding current signals, and sum the current signals to generate corresponding bit line signals.

In some embodiments, the memory blocks BK0_1 and BK0_1′ are configured to store a stored data bit SDT0_1. The memory blocks BK1_1 and BK1_1′ are configured to store a stored data bit SDT1_1, and so on. The memory blocks BK255_1 and BK255_1′ are configured to store a stored data bit SDT255_1.

Similarly, the memory blocks BK0_128K and BK0_128K′ are configured to store a stored data bit SDT0_128K. The memory blocks BK1_128K and BK1_128K′ are configured to store a stored data bit SDT1_128K, and so on. The memory blocks BK255_128K and BK255_128K′ are configured to store a stored data bit SDT255_128K.

On the other hand, the string select line signals SSL0 and SSL0′ are configured to carry an input bit IBT0. The string select line signals SSL1 and SSL1′ are configured to carry an input bit IBT1, and so on. The string select line signals SSL255 and SSL255′ are configured to carry an input bit IBT255.

During the search operation, the memory blocks BK0_1 and BK0_1′ are configured to compare the stored data bit SDT0_1 and the input bit IBT0 to generate the current signal IT0_1. The memory blocks BK1_1 and BK1_1′ are configured to compare the stored data bit SDT1_1 and the input bit IBT1 to generate the current signal IT1_1, and so on. The memory blocks BK255_1 and BK255_1′ are configured to compare the stored data bit SDT255_1 and the input bit IBT255 to generate the current signal IT255_1.

Similarly, the memory blocks BK0_128K and BK0_128K′ are configured to compare the stored data bit SDT0_128K and the input bit IBT0 to generate the current signal IT0_128K. The memory blocks BK1_128K and BK1_128K′ are configured to compare the stored data bit SDT1_128K and the input bit IBT1 to generate the current signal IT1_128K, and so on. The memory blocks BK255_128K and BK255_128K′ are configured to compare the stored data bit SDT255_128K and the input bit IBT255 to generate the current signal IT255_128K.

Correspondingly, the current level of the bit line signal BL1 is proportional to a pseudo-Euclidean distance between the input bits IBT0-IBT255 and the stored data bits SDT0_1-SDT255_1. The current level of the bit line signal BL128K is proportional to a pseudo-Euclidean distance between the input bits IBT0-IBT255 and the stored data bits SDT0_128K-SDT255_128K.

As shown in FIG. 6B, the memory block BK0_1 includes sub-blocks SBK0_1_1-SBK0_9_1. The sub-blocks SBK0_1_1-SBK0_9_1 include memory strings MS0_1_1-MS0_9_1, respectively. The memory block BK0_1′ includes sub-blocks SBK0_1_1′-SBK0_9_1′. The sub-blocks SBK0_1_1′-SBK0_9_1′ include memory strings MS0_1_1′-MS0_9_1′, respectively.

Similarly, the memory block BK0_128K includes sub-blocks SBK0_1_128K-SBK0_9_128K. The sub-blocks SBK0_1_128K-SBK0_9_128K include memory strings MS0_1_128K-MS0_9_128K, respectively. The memory block BK0_128K′ includes sub-blocks SBK0_1_128K′-SBK0_9_128K′. The sub-blocks SBK0_1_128K′-SBK0_9_128K′ include memory strings MS0_1_128K′-MS0_9_128K′, respectively.

Similarly, the memory block BK255_1 includes sub-blocks SBK255_1_1-SBK255_9_1. The sub-blocks SBK255_1_1-SBK255_9_1 include memory strings MS255_1_1-MS255_9_1, respectively. The memory block BK255_1′ includes sub-blocks SBK255_1_1′-SBK255_9_1′. The sub-blocks SBK255_1_1′-SBK255_9_1′ include memory strings MS255_1_1′-MS255_9_1′, respectively.

Similarly, the memory block BK255_128K includes sub-blocks SBK255_1_128K-SBK255_9_128K. The sub-blocks SBK255_1_128K-SBK255_9_128K include memory strings MS255_1_128K-MS255_9_128K, respectively. The memory block BK255_128K′ includes sub-blocks SBK255_1_128K′-SBK255_9_128K′. The sub-blocks SBK255_1_128K′-SBK255_9_128K′ include memory strings MS255_1_128K′-MS255_9_128K′, respectively.

FIG. 6C is a schematic diagram of further details of the memory blocks BK0_1 and BK0_1′, illustrated according to some embodiments of present disclosure. As shown in FIG. 6C, the memory string MS0_1_1 includes switch elements T0_1_1_0-T0_1_1_95 and TS0_1_1 coupled in series with each other. The memory string MS0_2_1 includes switch elements T0_2_1_0-T0_2_1_95 and TS0_2_1 coupled in series with each other, and so on. The memory string MS0_9_1 includes switch elements T0_9_1_0-T0_9_1_95 and TS0_9_1 coupled in series with each other.

Similarly, the memory string MS0_1_1′ includes switch elements T0_1_1_0′-T0_1_1_95′ and TS0_1_1′ coupled in series with each other. The memory string MS0_2_1′ includes switch elements T0_2_1_0′-T0_2_1_95′ and TS0_2_1′ coupled in series with each other, and so on. The memory string MS0_9_1′ includes switch elements T0_9_1_0′-T0_9_1_95′ and TS0_9_1′ coupled in series with each other. However, the embodiments of present disclosure are not limited to this. In various embodiments, the memory string can include various quantities of switch elements, that is, 95 can be substituted with other positive integers. For example, 95 can be substituted with 191.

In some embodiments, each of control terminals of the switch elements T0_1_1_0-T0_9_1_0 and T0_1_1_0′-T0_9_1_0′ is configured to receive the word line signal WL0. Each of control terminals of the switch elements T0_1_1_1-T0_9_1_1 and T0_1_1_1′-T0_9_1_1′ is configured to receive the word line signal WL1, and so on. Each of control terminals of the switch elements T0_1_1_93-T0_9_1_93 and T0_1_1_93′-T0_9_1_93′ is configured to receive the word line signal WL93. Each of control terminals of the switch elements T0_1_1_94-T0_9_1_94 and T0_1_1_94′-T0_9_1_94′ is configured to receive the word line signal WL94. Each of control terminals of the switch elements T0_1_1_95-T0_9_1_95 and T0_1_1_95′-T0_9_1_95′ is configured to receive the word line signal WL95. Each of control terminals of the switch elements TS0_1_1-TS0_9_1 is configured to receive the string select line signal SSL0. Each of control terminals of the switch elements TS0_1_1′-TS0_9_1′ is configured to receive the string select line signal SSL0′.

In the embodiment shown in FIG. 6C, the switch elements T0_1_1_95-T0_9_1_95 and T0_1_1_95′-T0_9_1_95′ are configured to store the stored data bit SDT0_1. The stored data bit SDT0_1 has the logic value 3, such that each of the switch elements T0_1_1_95-T0_9_1_95 has the threshold voltage level LVT, and each of the switch elements T0_1_1_95′-T0_9_1_95′ has the threshold voltage level HVT. On the other hand, the input bit IBT0 has the logic value 0 or 1, such that the string select line signals SSL0 and SSL0′ have the voltage levels HVSSL and LVSSL, respectively.

During the search operation, the word line signal WL95 has the read voltage level VREAD, and each of the word line signals WL0-WL94 has the pass voltage level VPASS. Correspondingly, the memory block BL0_1 generates 9 string current signals having the current level ISL1, such that the current level of the current signal IT0_1 is equal to the current level ISL1 multiplied by 9.

The condition of the memory blocks BK0_1 and BK0_1′ shown in FIG. 6C is similar with the condition of the memory blocks BK1 and BK1′ shown in FIG. 4D. Therefore, for brevity, some descriptions are not repeated.

FIG. 6D is a schematic diagram of further details of the memory blocks BK255_1 and BK255_1′, illustrated according to some embodiments of present disclosure. As shown in FIG. 6D, the memory string MS255_1_1 includes switch elements T255_1_1_0-T255_1_1_95 and TS255_1_1 coupled in series with each other. The memory string MS255_2_1 includes switch elements T255_2_1_0-T255_2_1_95 and TS255_2_1 coupled in series with each other, and so on. The memory string MS255_9_1 includes switch elements T255_9_1_0-T255_9_1_95 and TS255_9_1 coupled in series with each other.

Similarly, the memory string MS255_1_1′ includes switch elements T255_1_1_0′-T255_1_1_95′ and TS255_1_1′ coupled in series with each other. The memory string MS255_2_1′ includes switch elements T255_2_1_0′-T255_2_1_95′ and TS255_2_1′ coupled in series with each other, and so on. The memory string MS255_9_1′ includes switch elements T255_9_1_0′-T255_9_1_95′ and TS255_9_1′ coupled in series with each other.

In some embodiments, each of control terminals of the switch elements T255_1_1_0-T255_9_1_0 and T255_1_1_0′-T255_9_1_0′ is configured to receive the word line signal WL0. Each of control terminals of the switch elements T255_1_1_1-T255_9_1_1 and T255_1_1_1′-T255_9_1_1′ is configured to receive the word line signal WL1, and so on. Each of control terminals of the switch elements T255_1_1_93-T255_9_1_93 and T255_1_1_93′-T255_9_1_93′ is configured to receive the word line signal WL93. Each of control terminals of the switch elements T255_1_1_94-T255_9_1_94 and T255_1_1_94′-T255_9_1_94′ is configured to receive the word line signal WL94. Each of control terminals of the switch elements T255_1_1_95-T255_9_1_95 and T255_1_1_95′-T255_9_1_95′ is configured to receive the word line signal WL95. Each of control terminals of the switch elements TS255_1_1-TS255_9_1 is configured to receive the string select line signal SSL255. Each of control terminals of the switch elements TS255_1_1′-TS255_9_1′ is configured to receive the string select line signal SSL255′.

In the embodiment shown in FIG. 6D, the switch elements T255_1_1_95-T255_9_1_95 and T255_1_1_95′-T255_9_1_95′ are configured to store the stored data bit SDT255_1. The stored data bit SDT255_1 has the logic value 1, such that each of the switch elements T255_1_1_95 and T255_1_1_95′-T255_4_1_95′ has the threshold voltage level LVT, and each of the switch elements T255_2_1_95-T255_9_1_95 and T255_5_1_95′-T255_9_1_95′ has the threshold voltage level HVT. On the other hand, the input bit IBT255 has the logic value 2 or 3, such that the string select line signals SSL255 and SSL255′ have the voltage levels LVSSL and HVSSL, respectively.

During the search operation, the word line signal WL95 has the read voltage level VREAD, and each of the word line signals WL0-WL94 has the pass voltage level VPASS. Correspondingly, the memory block BL255_1′ generates 4 string current signals having the current level ISL1, such that the current level of the current signal IT255_1 is equal to the current level ISL1 multiplied by 4.

The condition of the memory blocks BK255_1 and BK255_1′ shown in FIG. 6D is similar with the condition of the memory blocks BK1 and BK1′ shown in FIG. 4F. Therefore, for brevity, some descriptions are not repeated.

FIG. 6E is a schematic diagram of further details of the memory blocks BK0_128K and BK0_128K′, illustrated according to some embodiments of present disclosure. As shown in FIG. 6E, the memory string MS0_1_128K includes switch elements T0_1_128K_0-T0_1_128K_95 and TS0_1_128K coupled in series with each other. The memory string MS0_2_128K includes switch elements T0_2_128K_0-T0_2_128K_95 and TS0_2_128K coupled in series with each other, and so on. The memory string MS0_9_128K includes switch elements T0_9_128K_0-T0_9_128K_95 and TS0_9_128K coupled in series with each other.

Similarly, the memory string MS0_1_128K′ includes switch elements T0_1_128K_0′-T0_1_128K_95′ and TS0_1_128K′ coupled in series with each other. The memory string MS0_2_128K′ includes switch elements T0_2_128K_0′-T0_2_128K_95′ and TS0_2_128K′ coupled in series with each other, and so on. The memory string MS0_9_128K′ includes switch elements T0_9_128K_0′-T0_9_128K_95′ and TS0_9_128K′ coupled in series with each other.

In some embodiments, each of control terminals of the switch elements T0_1_128K_0-T0_9_128K_0 and T0_1_128K_0′-T0_9_128K_0′ is configured to receive the word line signal WL0. Each of control terminals of the switch elements T0_1_128K_1-T0_9_128K_1 and T0_1_128K_1′-T0_9_128K_1′ is configured to receive the word line signal WL1, and so on. Each of control terminals of the switch elements T0_1_128K_93-T0_9_128K_93 and T0_1_128K_93′-T0_9_128K_93′ is configured to receive the word line signal WL93. Each of control terminals of the switch elements T0_1_128K_94-T0_9_128K_94 and T0_1_128K_94′-T0_9_128K_94′ is configured to receive the word line signal WL94. Each of control terminals of the switch elements T0_1_128K_95-T0_9_128K_95 and T0_1_128K_95′-T0_9_128K_95′ is configured to receive the word line signal WL95. Each of control terminals of the switch elements TS0_1_128K-TS0_9_128K is configured to receive the string select line signal SSL0. Each of control terminals of the switch elements TS0_1_128K′-TS0_9_128K′ is configured to receive the string select line signal SSL0′.

In the embodiment shown in FIG. 6E, the switch elements T0_1_128K_95-T0_9_128K_95 and T0_1_128K_95′-T0_9_128K_95′ are configured to store the stored data bit SDT0_128K. The stored data bit SDT0_128K has the logic value 0, such that each of the switch elements T0_1_128K_95-T0_9_128K_95 has the threshold voltage level HVT, and each of the switch elements T0_1_1_95′-T0_9_1_95′ has the threshold voltage level LVT. On the other hand, the input bit IBT0 has the logic value 0 or 1, such that the string select line signals SSL0 and SSL0′ have the voltage levels HVSSL and LVSSL, respectively.

During the search operation, the word line signal WL95 has the read voltage level VREAD, and each of the word line signals WL0-WL94 has the pass voltage level VPASS. Correspondingly, the memory blocks BK0_128K and BK0_128K′ generates 0 string current signals having the current level ISL1, such that the current level of the current signal IT0_128K is equal to the current level ISL1 multiplied by 0.

The condition of the memory blocks BK0_128K and BK0_128K′ shown in FIG. 6E is similar with the condition of the memory blocks BK1 and BK1′ shown in FIG. 4A. Therefore, for brevity, some descriptions are not repeated.

FIG. 6F is a schematic diagram of further details of the memory blocks BK255_128K and BK255_128K′, illustrated according to some embodiments of present disclosure. As shown in FIG. 6F, the memory string MS255_1_128K includes switch elements T255_1_128K_0-T255_1_128K_95 and TS255_1_128K coupled in series with each other. The memory string MS255_2_128K includes switch elements T255_2_128K_0-T255_2_128K_95 and TS255_2_128K coupled in series with each other, and so on. The memory string MS255_9_128K includes switch elements T255_9_128K_0-T255_9_128K_95 and TS255_9_128K coupled in series with each other.

Similarly, the memory string MS255_1_128K′ includes switch elements T255_1_128K_0′-T255_1_128K_95′ and TS255_1_128K′ coupled in series with each other. The memory string MS255_2_128K′ includes switch elements T255_2_128K_0′-T255_2_128K_95′ and TS255_2_128K′ coupled in series with each other, and so on. The memory string MS255_9_128K′ includes switch elements T255_9_128K_0′-T255_9_128K_95′ and TS255_9_128K′ coupled in series with each other.

In some embodiments, each of control terminals of the switch elements T255_1_128K_0-T255_9_128K_0 and T255_1_128K_0′-T255_9_128K_0′ is configured to receive the word line signal WL0. Each of control terminals of the switch elements T255_1_128K_1-T255_9_128K_1 and T255_1_128K_1′-T255_9_128K_1′ is configured to receive the word line signal WL1, and so on. Each of control terminals of the switch elements T255_1_128K_93-T255_9_128K_93 and T255_1_128K_93′-T255_9_128K_93′ is configured to receive the word line signal WL93. Each of control terminals of the switch elements T255_1_128K_94-T255_9_128K_94 and T255_1_128K_94′-T255_9_128K_94′ is configured to receive the word line signal WL94. Each of control terminals of the switch elements T255_1_128K_95-T255_9_128K_95 and T255_1_128K_95′-T255_9_128K_95′ is configured to receive the word line signal WL95. Each of control terminals of the switch elements TS255_1_128K-TS255_9_128K is configured to receive the string select line signal SSL255. Each of control terminals of the switch elements TS255_1_128K′-TS255_9_128K′ is configured to receive the string select line signal SSL255′.

In the embodiment shown in FIG. 6F, the switch elements T255_1_128K_95-T255_9_128K_95 and T255_1_128K_95′-T255_9_128K_95′ are configured to store the stored data bit SDT255_128K. The stored data bit SDT255_128K has the logic value 3, such that each of the switch elements T255_1_128K_95-T255_9_128K_95 has the threshold voltage level LVT, and each of the switch elements T255_1_1_95′-T255_9_1_95′ has the threshold voltage level HVT. On the other hand, the input bit IBT255 has the logic value 2 or 3, such that the string select line signals SSL255 and SSL255′ have the voltage levels LVSSL and HVSSL, respectively.

During the search operation, the word line signal WL95 has the read voltage level VREAD, and each of the word line signals WL0-WL94 has the pass voltage level VPASS. Correspondingly, the memory blocks BK255_128K and BK255_128K′ generates 0 string current signals having the current level ISL1, such that the current level of the current signal IT255_128K is equal to the current level ISL1 multiplied by 0.

The condition of the memory blocks BL255_128K and BL255_128K′ shown in FIG. 6F is similar with the condition of the memory blocks BL1 and BL1′ shown in FIG. 4H. Therefore, for brevity, some descriptions are not repeated.

In some embodiments, the search operations shown in FIG. 6C to FIG. 6F can be performed simultaneously. Alternatively stated, the memory device 610 can compare the input bit IBT0 with the stored data bits SDT0_1-SDT0_128K simultaneously, and compare the input bit IBT255 with the stored data bits SDT255_1-SDT255_128K simultaneously.

In some embodiments, when a current level of a bit line signal is lower, a similarity between corresponding stored data bits and the input bits IBT0-IBT255 is higher, that is, a corresponding pseudo-Euclidean distance is smaller.

For example, in the embodiments shown in FIG. 6C to FIG. 6F, the current level of the bit line signal BL128K is lower than the current level of the bit line signal BL1. Correspondingly, a similarity between the stored data bits SDT0_128K-SDT255_128K and the input bits IBT0-IBT255 is higher a similarity between the stored data bits SDT0_1-SDT255_1 and the input bits IBT0-IBT255.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or ferroelectric field-effect transistor (FeFET).

In various embodiments, the memory device 510 can be implemented by various structures, such as 2D-NAND flash structure, 3D-NAND flash structure, 2D-NOR flash structure or 3D-NOR flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a first memory block pair, the first memory block pair configured to store a first stored data bit, and configured to compare the first stored data bit and a first input bit, to generate a first current signal, the first memory block pair comprising:
a first memory block configured to generate a plurality of first string current signals according to a first string select line signal; and
a second memory block configured to generate a plurality of second string current signals according to a second string select line signal,
wherein the first string select line signal and the second string select line signal are configured to carry the first input bit, and
the first memory block pair is further configured to sum the plurality of first string current signals and the plurality of second string current signals to generate the first current signal.

2. The memory device of claim 1, wherein
the first memory block is further configured to sum the plurality of first string current signals to generate a second current signal,
the second memory block is further configured to sum the plurality of second string current signals to generate a third current signal,
when the first stored data bit has a first logic value and the first input bit has the first logic value or a second logic value, each of the second current signal and the third current signal has a first current level.

3. The memory device of claim 2, wherein when the first stored data bit has the second logic value and the first input bit has the first logic value or the second logic value, the second current signal and the third current signal have a second current level and the first current level, respectively, and
the second current level is larger than the first current level.

4. The memory device of claim 3, wherein when the first stored data bit has a third logic value and the first input bit has the first logic value or the second logic value, the second current signal and the third current signal have a third current level and the first current level, respectively, and
the third current level is larger than the second current level.

5. The memory device of claim 4, wherein when the first stored data bit has a fourth logic value and the first input bit has the first logic value or the second logic value, the second current signal and the third current signal have a fourth current level and the first current level, respectively, and
the fourth current level is larger than the third current level.

6. The memory device of claim 4, wherein when the first stored data bit has the second logic value and the first input bit has the third logic value or a fourth logic value, the second current signal and the third current signal have the first current level and the third current level, respectively.

7. The memory device of claim 1, wherein
when the first input bit has a first logic value or a second logic value, the first string select line signal and the second string select line signal have a first voltage level and a second voltage level, respectively, and
when the first input bit has a third logic value or a fourth logic value, the first string select line signal and the second string select line signal have the second voltage level and the first voltage level, respectively.

8. The memory device of claim 7, wherein the first memory block comprising a first memory string and a second memory string,
when the first stored data bit has the first logic value, each of the first memory string and the second memory string has a first resistance, and
when the first stored data bit has the second logic value, the first memory string and the second memory string have a second resistance and the first resistance, respectively.

9. The memory device of claim 8, wherein when the first stored data bit has the third logic value, each of the first memory string and the second memory string has the second resistance.

10. The memory device of claim 9, wherein the first memory block further comprising a third memory string,
when the first stored data bit has the third logic value, the third memory string has the first resistance, and
when the first stored data bit has the fourth logic value, each of the first memory string, the second memory string and the third memory string has the second resistance.

11. A memory device, comprising:
a first memory block configured to generate a plurality of first string current signals according to a first string select line signal, and sum the plurality of first string current signals to generate a first current signal; and
a second memory block configured to generate a plurality of second string current signals according to a second string select line signal, and sum the plurality of second string current signals to generate a second current signal,
wherein the first string select line signal and the second string select line signal are configured to carry a first input bit,
the first memory block and the second memory block are further configured to store a first stored data bit, and
when a logic value of the first input bit is equal to a logic value of the first stored data bit, a current level of the first current signal is equal to a current level of the second current signal.

12. The memory device of claim 11, wherein when the logic value of the first input bit is different from the logic value of the first stored data bit, the current level of the first current signal is different from the current level of the second current signal.

13. The memory device of claim 11, wherein the first memory block and the second memory block comprise a first switch element and a second switch element, respectively,
when the first stored data bit has a first logic value, the first switch element and the second switch element have a first threshold voltage level and a second threshold voltage level, respectively, and
when the first stored data bit has a second logic value, each of the first switch element and the second switch element has the second threshold voltage level.

14. The memory device of claim 13, wherein when the first stored data bit has a third logic value, the first switch element and the second switch element have the second threshold voltage level and the first threshold voltage level, respectively.

15. The memory device of claim 13, wherein the first memory block and the second memory block comprise a third switch element and a fourth switch element, respectively,
when the first stored data bit has a first logic value, the third switch element and the fourth switch element have a first threshold voltage level and the second threshold voltage level, respectively, and
when the first stored data bit has a second logic value, each of the third switch element and the fourth switch element has the second threshold voltage level.

16. The memory device of claim 15, wherein when the first stored data bit has a third logic value, each of the first switch element and the third switch element has the second threshold voltage level, and each of the second switch element and the fourth switch element has the first threshold voltage level.

17. The memory device of claim 13, wherein the first memory block and the second memory block comprise a third switch element and a fourth switch element, respectively,
the third switch element and the fourth switch element are configured to receive the first string select line signal and the second string select line signal, respectively,
when the first input bit has the first logic value or the second logic value, the first string select line signal and the second string select line signal has a first voltage level and a second voltage level, respectively,
when the first input bit has a third logic value or a fourth logic value, the first string select line signal and the second string select line signal has the second voltage level and the first voltage level, respectively,
the first logic value, the second logic value, the third logic value and the fourth logic value are different from each other.

18. A memory system, comprising:
a plurality of first memory blocks configured to store a plurality of first stored data bits, and configured to compare the plurality of first stored data bits with a plurality of input bits to generate a first bit line signal; and
a plurality of second memory blocks configured to store a plurality of second stored data bits, and configured to compare the plurality of second stored data bits with the plurality of input bits to generate a second bit line signal,
wherein the plurality of first memory blocks and the plurality of second memory blocks are further configured to receive a plurality of string select line signals, and
the plurality of string select line signals are configured to carry the plurality of input bits.

19. The memory system of claim 18, wherein the plurality of first memory blocks comprise a third memory block and a fourth memory block respectively configured to receive a first string select line signal and a second string select line signal,
the third memory block and the fourth memory block are configured to store a third stored data bit in the plurality of first stored data bits,
in response to a first input bit in the plurality of input bits having a first logic value or a second logic value, the first string select line signal and the second string select line signal have a first voltage level and a second voltage level, respectively, and
the first voltage level is larger than the second voltage level.

20. The memory system of claim 19, wherein the plurality of second memory blocks comprise a fifth memory block and a sixth memory block respectively configured to receive the first string select line signal and the second string select line signal,
the fifth memory block and the sixth memory block configured to store a fourth stored data bit in the plurality of second stored data bits,
in response to the third stored data bit having a third logic value, the third memory block and the fourth memory block are configured to generate a first current signal having a first current level,
in response to the fourth stored data bit having the first logic value, the third memory block and the fourth memory block are configured to generate a second current signal having a second current level, and
the first current level is larger than the second current level.
